(19) United States
(12) Patent Application Publication
(10) Pub. No.: US 2026/0081551 A1
(43) Pub. Date: Mar. 19, 2026

(54) METHODS AND APPARATUS TO SENSE A STATE OF ISOLATION IN GATE DRIVER CIRCUITRY

(71) Applicant: Texas Instruments Incorporated, Dallas, TX (US)

(72) Inventors: Aiyappa Byrajanda Naniappa, Raleigh, NC (US); Martin Staebler, Freising (DE); Aswin Srinivasa Rao, San Jose, CA (US)

(21) Appl. No.: 18/885,150

(22) Filed: Sep. 13, 2024

(51) Int. Cl. H02P 27/08; H02P 21/00; H03K 17/296; H03K 17/691

(52) U.S. Cl. CPC H02P 27/085; H02P 21/0003; H03K 17/296; H03K 17/691

(57) ABSTRACT

An example apparatus includes: charge injection circuitry having a first terminal, a second terminal, and a control terminal; first inductor-capacitor (LC) circuitry having a first terminal and a second terminal, the first terminal of the first LC circuitry coupled to the first terminal of the charge injection circuitry, the second terminal of the first LC circuitry coupled to the second terminal of the charge injection circuitry; second LC circuitry magnetically coupled to the first LC circuitry; and current sense circuitry having an input terminal coupled to the control terminal of the charge injection circuitry.

### TECHNICAL FIELD

This description relates generally to gate driver circuitry and, more particularly, to methods and apparatus to sense a state of isolated gate driver circuitry.

### BACKGROUND

Gate driver circuitry generates relatively high-power signals that control transistor circuitry responsive to relatively lower power signals. Gate driver circuitry allows programmable circuitry to control a wide range of transistors using digital signals that have lower power as compared to the higher power signals needed to drive the gate for some transistors. Isolated gate driver circuitry includes isolation circuitry to isolate voltages of the relatively low power digital signals from voltages of the relatively higher power signals.

### SUMMARY

For methods and apparatus to sense a state of isolated gate driver circuitry, an example apparatus includes charge injection circuitry having a first terminal, a second terminal, and a control terminal; first inductor-capacitor (LC) circuitry having a first terminal and a second terminal, the first terminal of the first LC circuitry coupled to the first terminal of the charge injection circuitry, the second terminal of the first LC circuitry coupled to the second terminal of the charge injection circuitry; second LC circuitry magnetically coupled to the first LC circuitry; and current sense circuitry having an input terminal coupled to the control terminal of the charge injection circuitry. Other examples are described.

For methods and apparatus to sense a state of isolated gate driver circuitry, an example apparatus includes charge injection circuitry having a first terminal, a second terminal, and a control terminal; a transformer having a first input terminal, a second input terminal, a first output terminal, and a second output terminal, the first input terminal of the transformer is coupled to the first terminal of the charge injection circuitry, the second input terminal of the transformer is coupled to the second terminal of the charge injection circuitry; current sense circuitry having an input terminal coupled to the control terminal of the charge injection circuitry; and receiver circuitry having a first input terminal and a second input terminal, the first input terminal of the receiver circuitry is coupled to the first output terminal of the transformer, the second input terminal of the receiver circuitry is coupled to the second output terminal of the transformer. Other examples are described.

For methods and apparatus to sense a state of isolated gate driver circuitry, an example apparatus includes example gate driver circuitry configured to: receive a pulse width modulation (PWM) signal, generate a current based on a logical state of the PWM signal, and generate a sinusoidal signal in response to the current, and current sense circuitry configured to: sense the generation of the current by the isolated gate driver circuitry, and set a logical state of a safe signal in response to sensing the generation of the current. Other examples are described.

### BRIEF DESCRIPTION OF THE DRAWINGS

FIG. 1 is a block and schematic diagram of an example control system including example isolated gate driver circuitry and example programmable circuitry.

FIG. 2 is a schematic diagram of an example of the isolated gate driver circuitry of FIG. 1 including example charge injection circuitry and example current sense circuitry.

FIG. 3A is a schematic diagram of another example of the control system of FIG. 1 including example output stage circuitry.

FIG. 3B is a schematic diagram of yet another example of the control system of FIG. 1 including another example of the output stage circuitry of FIG. 3A.

FIG. 4 is a flowchart representative of example machine-readable instructions or example operations that may be at least one of executed, instantiated, or preformed using an example implementation of the isolated gate driver circuitry of FIGS. 1 and 2, the programmable circuitry of FIG. 1, or more generally, the control system of FIGS. 1, 3A, and 3B.

FIG. 5 is a timing diagram of example operations of the isolated gate driver circuitry of FIGS. 1 and 2 to sense a safe state indication.

FIG. 6 is a block diagram of an example implementation of the programmable circuitry of FIG. 1 to sense the safe state indication of the isolated gate driver circuitry of FIGS. 1 and 2.

FIG. 7 is a flowchart representative of example machine-readable instructions or example operations that may be at least one of executed, instantiated, or performed using an example implementation of the programmable circuitry of FIGS. 1 and 6 to verify the safe state of the isolated gate driver circuitry of FIGS. 1 and 2.

FIG. 8 is a timing diagram of example operations of the programmable circuitry of FIGS. 1 and 6 to sense a safety state of the isolated gate driver circuitry of FIGS. 1 and 2.

FIG. 9 is a block diagram of an example processing platform including programmable circuitry structured to execute, instantiate, or perform the example machine-readable instructions or perform the example operations of FIGS. 4 and 7 to implement the programmable circuitry of FIGS. 1 and 6, the isolated gate driver circuitry of FIGS. 1 and 2 or more generally the control system of FIGS. 1, 3A, and 3B.

FIG. 10 is a block diagram of an example implementation of the programmable circuitry of FIG. 9.

FIG. 11 is a block diagram of another example implementation of the programmable circuitry of FIG. 9.

The drawings are not necessarily to scale. Generally, the same reference numbers in the drawing(s) and this description refer to the same or similar (functionally and/or structurally) features and/or parts. Although the drawings show regions with clean lines and boundaries, some or all of these lines and boundaries may be idealized. In reality, the boundaries or lines may be unobservable, blended or irregular.

### DETAILED DESCRIPTION

Gate driver circuitry generates relatively high-power signals that control transistor circuitry responsive to relatively lower power signals. Gate driver circuitry allows programmable circuitry to control a wide range of transistors with relatively low power digital signals. Isolated gate driver circuitry includes isolation circuitry to isolate voltages of the relatively low power digital signals from voltages of the relatively higher power signals.

Motors convert electrical power into torque, which rotates an axle. Motor control systems control the amount of torque, direction of rotation, and speed of rotation by modifying the supply of electrical power to motor windings. Some control systems utilize a pulse width modulation (PWM) signal to supply power to the motor. The control system modifies the duty cycle of the PWM signal to adjust the supply of power to the motor, which adjusts the torque. Some motors, referred to as multi-phase motors, use a series of PWM signals to cause a rotation of the motor. The control system regulates the supply of power to the multi-phase motor by adjusting the phase of a reference PWM signal. Multi-phase motors allow the control system to control the position of the multi-phase motor by sequencing the supply of power by one or more PWM signals having different phases. Control systems may control the speed of rotation of the motor by adjusting the frequency of the PWM signals. Adjusting the frequency of the PWM signals to adjust the speed of rotation is referred to as variable frequency control.

Control systems include driver circuitry, which allow the control system to use a relatively low power PWM signal to accurately control a relatively high-power component, such as a motor. Driver circuitry includes a high-side transistor, a low-side transistor, high-side gate driver circuitry, and low-side gate driver circuitry. The high-side transistor controls the supply of power from a power supply, such as positive DC bus power supply, to a load based on the high-side gate driver circuitry. The low-side transistor controls the supply of power from the load to a common potential (e.g., ground) or a negative DC bus power supply based on the low-side gate driver circuitry. In operation, the high-side gate driver circuitry causes the high-side transistor to conduct current responsive to a logical high state of the PWM signal. In such operations, the low-side gate driver circuitry causes the low-side transistor to conduct current responsive to a logical low state of the PWM signal. However, to support transistor switching at increasingly large supply voltages the gate driver circuitry needs to generate increasingly large gate control voltages.

Opto-isolated gate driver circuitry may include a load switch, a Schottky diode, a capacitor, a light emitting diode (LED), a light sensor, and programmable circuitry. The load switch couples a supply voltage (VCC) to the Schottky diode based on a pulse from the programmable circuitry. The Schottky diode supplies current to the capacitor and an anode of the LED responsive to the programmable circuitry closing the load switch. The LED transmits data to the light sensor based on a PWM signal. Opto-isolated gate driver circuitry operates a primary side having the load switch, the Schottky diode, the capacitor, and the LED using first voltages. A secondary side of the opto-isolated gate driver circuitry having the light sensor operates using second voltages that are greater than the first voltages. Opto-isolated gate driver circuitry uses the light sensor to sense light from the LED, which represents data of the PWM signal. During a safe shut off event, such as a safe torque off (STO) event, the programmable circuitry opens the load switch to prevent the supply of current to the LED, which prevents the secondary side from controlling a transistor. However, in systems that need additional safety features, the opto-isolated gate driver circuitry cannot sense un-safe operating conditions after the load switch.

Complementary metal oxide semiconductor (CMOS) isolated gate driver circuitry includes a load switch, a Schottky diode, a capacitor, charge injection circuitry, a transformer, and programmable circuitry. The load switch couples a supply voltage (VCC) to the Schottky diode based on a pulse from the programmable circuitry. The Schottky diode supplies power to the charge injection circuitry responsive to the programmable circuitry closing the load switch. The charge injection circuitry excites a primary side of an LC circuit of the transformer to generate a sinusoidal signal based on a logical state of a PWM signal. The charge injection circuitry represents a logical one of the PWM signal by exciting the LC circuit and logical zeros by not exciting the LC circuit. The sinusoidal signal induces a current in a secondary side of the transformer, which has another LC circuit. The induced current drives the gate of a transistor. During a safety shut off event, such as an STO event, the programmable circuitry opens the load switch to prevent the supply of power to the charge injection circuitry, which prevents the secondary side from driving a transistor. However, in systems that need additional safety features, the CMOS-isolated gate driver circuitry cannot sense un-safe operating conditions after the load switch.

Some gate driver circuitry includes clamp circuitry between the Schottky diode and the charge injection circuitry. During a shut off event, the clamp circuitry couples the input of the charge injection circuitry or the anode side of the LED to a common potential (e.g., ground). Such a redundant safety feature reduces the likelihood of an adverse operating condition resulting in continued operation of the gate driver circuitry after a shut off event.

Some gate driver circuitry includes a comparator and additional isolation path to sense safe operating conditions. The comparator generates a safe signal responsive to a comparison of the output of the gate driver circuitry to a reference voltage. The comparator supplies the safe signal to the programmable circuitry across the additional isolation path. The programmable circuitry determines whether the gate driver circuitry is safely operating responsive to a comparison of the safe signal to the PWM signal. Such sensing using opto-isolated gate driver circuitry needs an additional LED and light sensor to isolate a safe signal of the secondary side from voltages of the primary side. CMOS isolated gate driver circuitry needs an additional transformer and current injection circuitry to isolate the safe signal of the secondary side from the primary side. Such additional circuitry increases the system-on-chip (SoC) size of the gate driver circuitry.

Examples described herein include methods and apparatus to sense a state of isolated gate driver circuitry. In some described examples, the isolated gate driver circuitry includes charge injection circuitry, transformer circuitry, receiver circuitry, and current sense circuitry. The charge injection circuitry supplies current to the transformer responsive to a PWM signal. In example operation, the charge injection circuitry supplies current to the transformer circuitry responsive to a logical one state of the PWM signal. In such example operations, the current from the charge injection circuitry excites a primary side LC circuit of the transformer circuitry, which generates a sinusoidal signal to traverse an isolation barrier. A secondary side LC circuit of the transformer circuitry conducts current responsive to the sinusoidal signal from the primary side LC circuit. The receiver circuitry generates a gate control signal responsive to the current from the secondary side LC circuit of the transformer circuitry.

The current sense circuitry is coupled to the control terminal of the charge injection circuitry, which controls the supply of current to the transformer circuitry. The current sense circuitry generates a safe signal based on the conduction of current by the charge injection circuitry. In such examples, programmable circuitry may determine a state of operation of the isolated gate driver circuitry responsive of a comparison of the safe signal to the PWM signal. For example, the programmable circuitry senses that the isolated gate driver circuitry is not in a safe operating state responsive to the safe signal indicating that the current injection circuitry is supplying current to the transformer circuitry. In such examples, the PWM signal has a logical state that should not result in the supply of current to the transformer circuitry. Advantageously, the isolated gate driver circuitry described herein senses currents to the transformer circuitry to determine a state of the isolated gate driver circuitry.

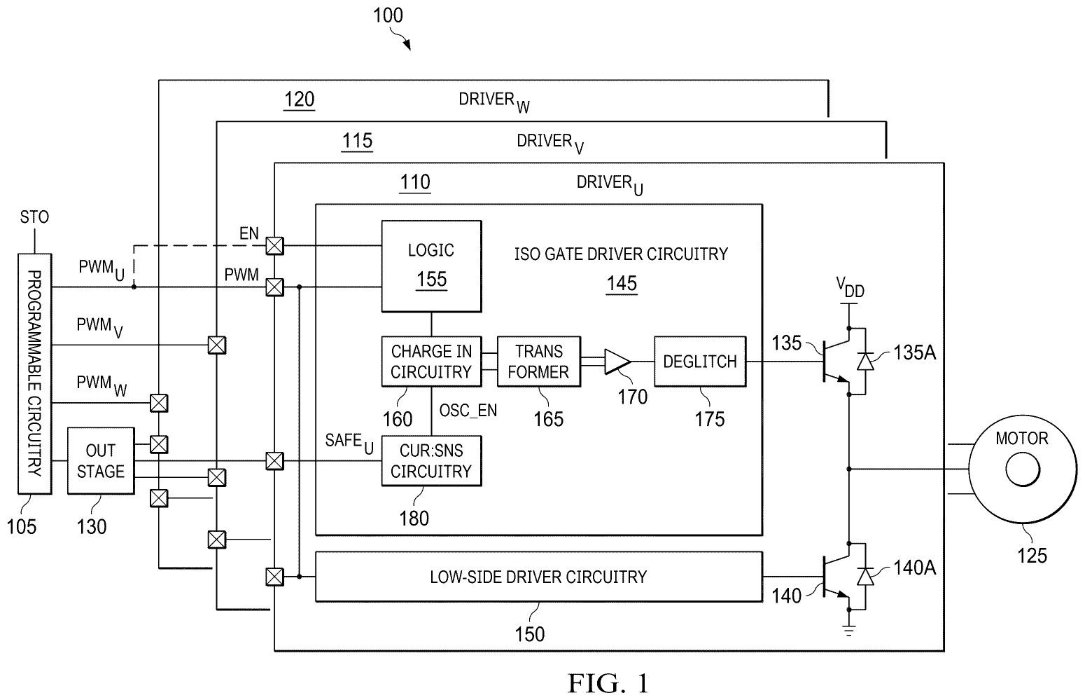

FIG. 1 is a block diagram of an example control system 100. In the example of FIG. 1, the control system 100 includes programmable circuitry 105, first driver circuitry 110, second driver circuitry 115, third driver circuitry 120, a motor 125, and output stage circuitry 130. The example driver circuitry 110 of FIG. 1 includes a first example transistor 135, a second example transistor 140, first example isolated gate driver circuitry 145, and second example isolated gate driver circuitry 150. The example isolated driver circuitry 145 of FIG. 1 includes example logic circuitry 155, example charge injection circuitry 160, example transformer circuitry 165, example receiver circuitry 170, example deglitch circuitry 175, and example current sense circuitry 180.

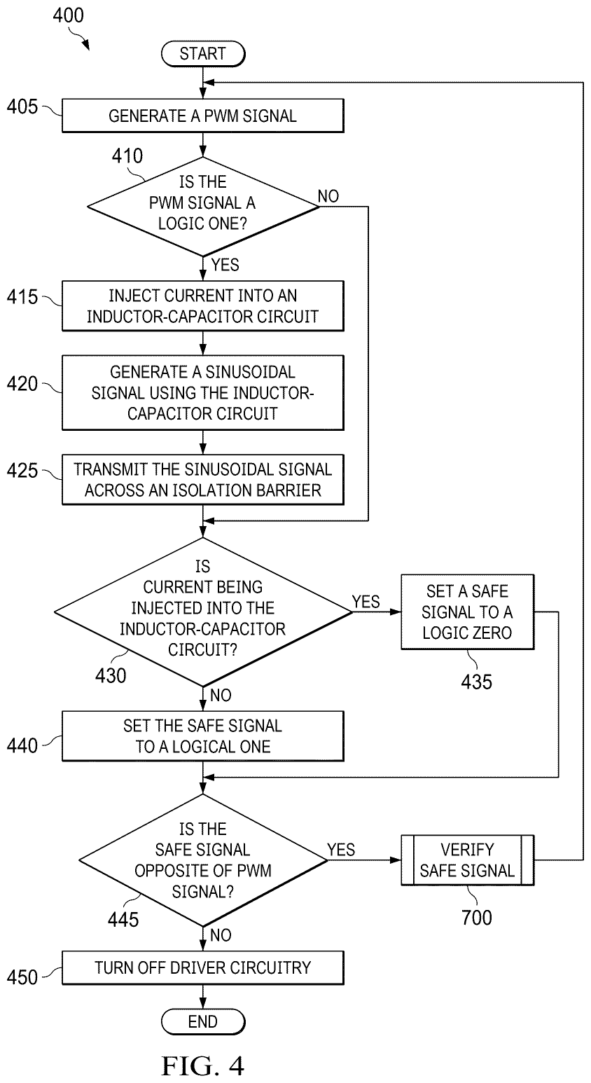

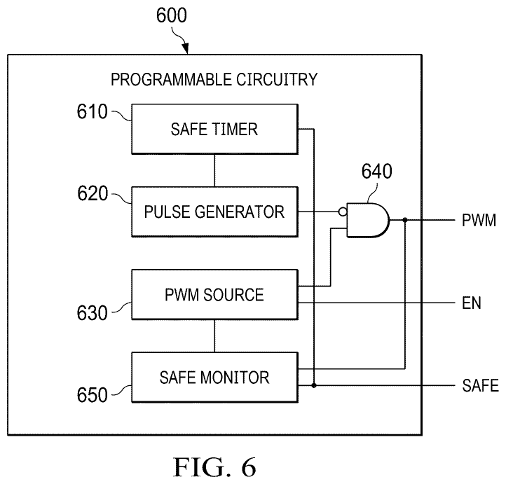

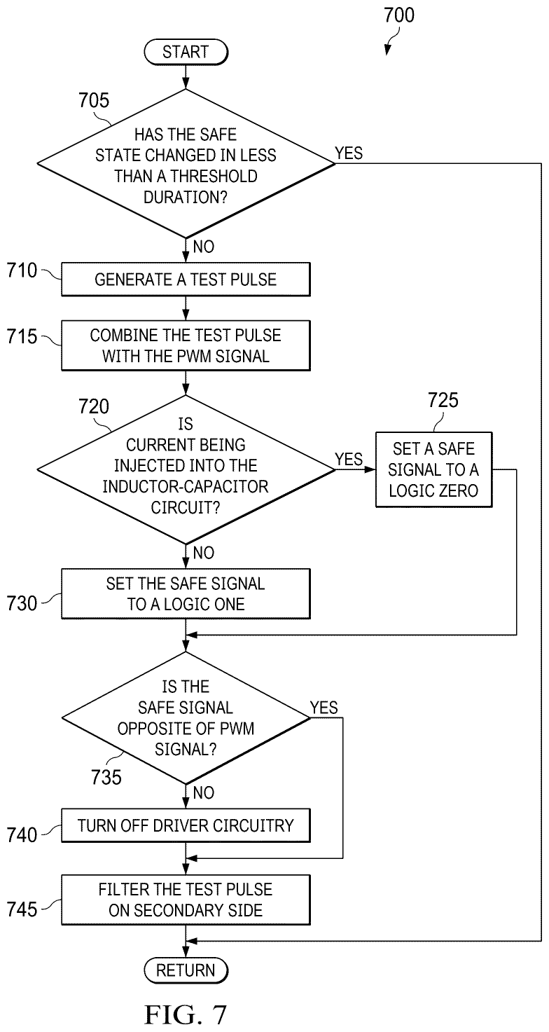

The programmable circuitry 105 has a first terminal, a second terminal, a third terminal, a fourth terminal, and a fifth terminal. The first terminal of the programmable circuitry 105 is coupled to a safe torque off (STO) input terminal of the control system 100, which supplies an STO signal. The STO signal represents an indication to remove torque generating power to the motor 125. The second terminal of the programmable circuitry 105 is coupled to the driver circuitry 110. The third terminal of the programmable circuitry 105 is coupled to the driver circuitry 115. The fourth terminal of the programmable circuitry 105 is coupled to the driver circuitry 120. The fifth terminal of the programmable circuitry is coupled to the output stage circuitry 130. In some examples, the programmable circuitry 105 is illustrated or described as a safe micro control unit (MCU), programmable logic device, logic circuitry, which include redundant safety features. The redundant safety features reduce the likelihood of inaccurately controlling the driver circuitry 110, 115, 120 and improve safety by reducing inaccuracies of the control system 100. Examples of the programmable circuitry 105 are further illustrated and described in connection with FIGS. 6, 9, 10, and 11, below. Example operations of the programmable circuitry are illustrated and described in connection with FIGS. 4 and 7, below.

The driver circuitry 110 has a first terminal, a second terminal, and a third terminal. The first terminal of the driver circuitry 110 is coupled to the programmable circuitry 105. The second terminal of the driver circuitry 110 is coupled to the motor 125. The third terminal of the driver circuitry 110 is coupled to the output stage circuitry 130.

The driver circuitry 115 has a first terminal, a second terminal, and a third terminal. The first terminal of the driver circuitry 115 is coupled to the programmable circuitry 105. The second terminal of the driver circuitry 115 is coupled to the motor 125. The third terminal of the driver circuitry 115 is coupled to the output stage circuitry 130.

The driver circuitry 120 has a first terminal, a second terminal, and a third terminal. The first terminal of the driver circuitry 120 is coupled to the programmable circuitry 105. The second terminal of the driver circuitry 120 is coupled to the motor 125. The third terminal of the driver circuitry 120 is coupled to the output stage circuitry 130.

The motor 125 has a first terminal, a second terminal, and a third terminal. The first terminal of the motor 125 is coupled to the driver circuitry 110. The second terminal of the motor 125 is coupled to the driver circuitry 115. The third terminal of the motor 125 is coupled to the driver circuitry 120. In some examples, the motor 125 is structured to convert electrical power from the driver circuitry 110, 115, 120 into mechanical power. Although in the example of FIG. 1, the control system 100 is structured to control the motor 125, in other examples, the control system 100 may be modified to supply electrical power to an alternative component.

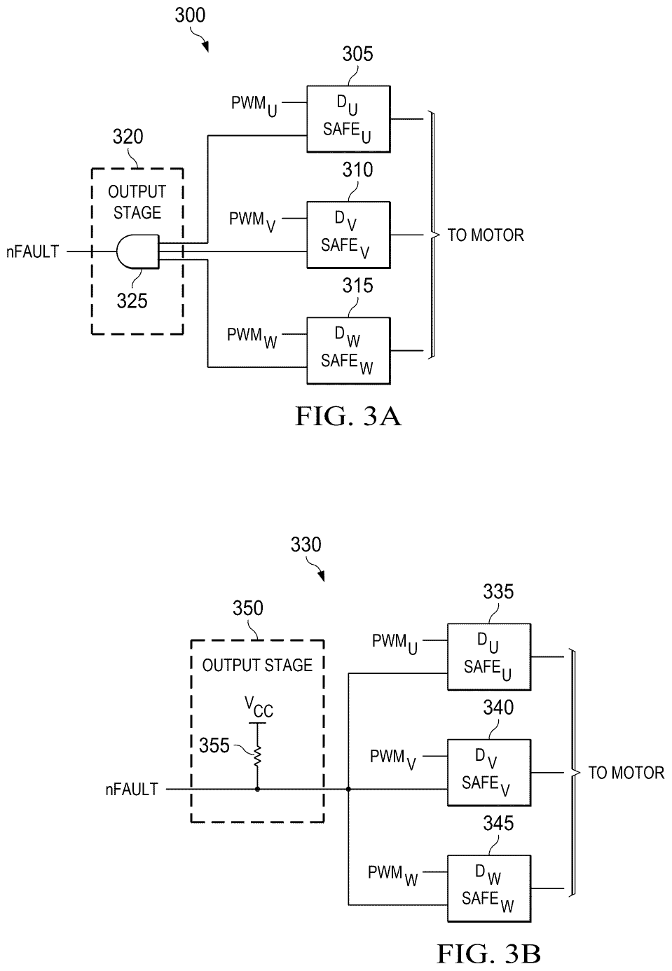

The output stage circuitry 130 has a first terminal, a second terminal, a third terminal, and a fourth terminal. The first terminal of the output stage circuitry 130 is coupled to the driver circuitry 110. The second terminal of the output stage circuitry 130 is coupled to the driver circuitry 115. The third terminal of the output stage circuitry 130 is coupled to the driver circuitry 120. The fourth terminal of the output stage circuitry 130 is coupled to the programmable circuitry 105. Examples of the output stage circuitry 130 are further illustrated and described in connection with FIGS. 3A and 3B, below.

The transistor 135 has a first terminal, a second terminal, and a control terminal. In the example of FIG. 1, the transistor 135 further has an example body diode 135A, which is a characteristic of implementing the transistor 135 in a die. In other examples, the body diode 135A may not be illustrated or described. The first terminal of the transistor 135 is coupled to a supply terminal, which supplies a supply voltage (V_{DD}). The second terminal of the transistor 135 is coupled to the motor 125 and the transistor 140. The control terminal of the transistor 135 is coupled to the isolated gate driver circuitry 145.

The transistor 140 has a first terminal, a second terminal, and a control terminal. In the example of FIG. 1, the transistor 140 further has an example body diode 140A, which is a characteristic of implementing the transistor 140 in a die. In other examples, the body diode 140A may not be illustrated or described. The first terminal of the transistor 140 is coupled to the motor 125 and the transistor 135. The second terminal of the transistor 140 is coupled to a common terminal, which supplies a common potential (e.g., ground, AVDD, etc.). The control terminal of the transistor 140 is coupled to the isolated gate driver circuitry 150. In the example of FIG. 1, the transistors 135, 140 form half bridge circuitry, which drives an output of the driver circuitry 110 responsive to switching of the transistors 135, 140. In such examples, the transistor 135 and the isolated gate driver circuitry 145 are referred to as high-side components, which control a supply of power from the supply terminal to the motor 125. Also, the transistor 140 and the isolated gate driver circuitry 150 are referred to as low-side components, which control a supply of power from the motor 125 to the common terminal.

In the example of FIG. 1, the transistors 135, 140 are NPN bipolar junction transistors (BJTs). Alternatively, the transistors 135, 140 may be n-channel field-effect transistors (FETs), n-channel insulated-gate bipolar transistors (IGBTs), n-channel junction field effect transistors (JFETs), n-channel metal-oxide semiconductor field-effect transistors (MOSFETs) or, with slight modifications, p-type equivalent devices. The transistors 135, 140 may be depletion mode devices, drain-extended devices, enhancement mode devices, natural transistors, or other type of device structure transistors. Furthermore, the transistors 135, 140 may be implemented in/over a silicon substrate (Si), a silicon carbide substrate (SiC), a gallium nitride substrate (GaN) or a gallium arsenide substrate (GaAs).

The isolated gate driver circuitry 145 has a first terminal, a second terminal, and a third terminal. The first terminal of the isolated gate driver circuitry 145 is coupled to the programmable circuitry 105. The second terminal of the isolated gate driver circuitry 145 is coupled to the transistor 135. The third terminal of the isolated gate driver circuitry 145 is coupled to the output stage circuitry 130. In some examples, the isolated gate driver circuitry 145 further has a fourth terminal coupled to the programmable circuitry 105. In such examples, the programmable circuitry 105 is structured to supply an enable signal (EN), which can prevent (e.g., disable) the isolated gate driver circuitry 145 from controlling the transistor 135.

The isolated gate driver circuitry 150 has a first terminal, a second terminal, and a third terminal. The first terminal of the isolated gate driver circuitry 150 is coupled to the programmable circuitry 105. The second terminal of the isolated gate driver circuitry 150 is coupled to the transistor 140. The third terminal of the isolated gate driver circuitry 150 is structured to be coupled to an output stage circuitry, such as the output stage circuitry 130. In some examples, the control system 100 includes multiple instances of the output stage circuitry 130. For example, the control system 100 includes first and second instances of the output stage circuitry 130. In such examples, the first instance of the output stage circuitry 130 is specific to the high-side isolated gate driver circuitry 145 of the driver circuitry 110, 115, 120 and the second instance of the output stage circuitry 130 is specific to the low-side isolated gate driver circuitry 150 of the driver circuitry 110, 115, 120. In some examples, the isolated gate driver circuitry 150 further has a fourth terminal coupled to the programmable circuitry 105. In such examples, the programmable circuitry 105 is structured to supply an enable signal (EN), which can prevent the isolated gate driver circuitry 150 from controlling the transistor 140.

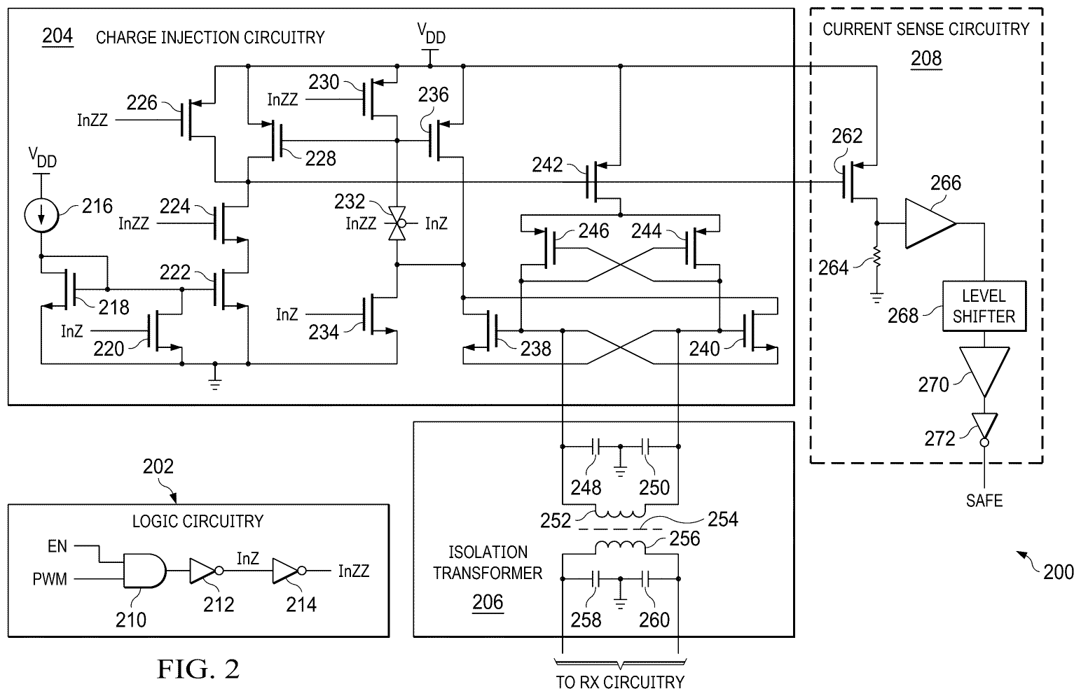

The logic circuitry 155 has a first terminal and a second terminal. The first terminal of the logic circuitry 155 is coupled to the programmable circuitry 105. The second terminal of the logic circuitry 155 is coupled to the charge injection circuitry 160. In some examples, the logic circuitry 155 further has a third terminal coupled to the programmable circuitry 105. In such examples, the programmable circuitry 105 supplies the enable signal to the logic circuitry 155. An example of the logic circuitry 155 is further illustrated and described in connection with FIG. 2, below.

The charge injection circuitry 160 has a first terminal, a second terminal, a third terminal, and a fourth terminal. The first terminal of the charge injection circuitry 160 is coupled to the logic circuitry 155. The second and third terminals of the charge injection circuitry 160 are coupled to the transformer circuitry 165. The fourth terminal of the charge injection circuitry 160 is coupled to the current sense circuitry 180. An example of the charge injection circuitry 160 is further illustrated and described in connection with FIG. 2, below. Example operations of the charge injection circuitry 160 are illustrated and described in connection with FIG. 4, below.

The transformer circuitry 165 has a first terminal, a second terminal, a third terminal, and a fourth terminal. The first and second terminals of the transformer circuitry 165 are coupled to the charge injection circuitry 160. The third and fourth terminals of the transformer circuitry 165 are coupled to the receiver circuitry 170. In some examples, the transformer circuitry 165 is referred to as an isolation transformer, which uses galvanic isolation to electrically isolate the charge injection circuitry 160 from the receiver circuitry 170. An example of the transformer circuitry 165 is further illustrated and described in connection with FIG. 2, below.

The receiver circuitry 170 has a first terminal, a second terminal, and a third terminal. The first and second terminals are coupled to the transformer circuitry 165. The third terminal of the receiver circuitry 170 is coupled to the deglitch circuitry 175. In some examples, the receiver circuitry 170 is amplifier circuitry structured to generate an output responsive to currents from the transformer circuitry 165.

The deglitch circuitry 175 has a first terminal and a second terminal. The first terminal of the deglitch circuitry 175 is coupled to the receiver circuitry 170. The second terminal of the deglitch circuitry 175 is coupled to the transistor 135. In some examples, the deglitch circuitry 175 is structured as a filter, which removes relatively high frequency signals from the output of the isolated gate driver circuitry 145. Example operations of the deglitch circuitry 175 are further illustrated and described in connection to FIG. 7.

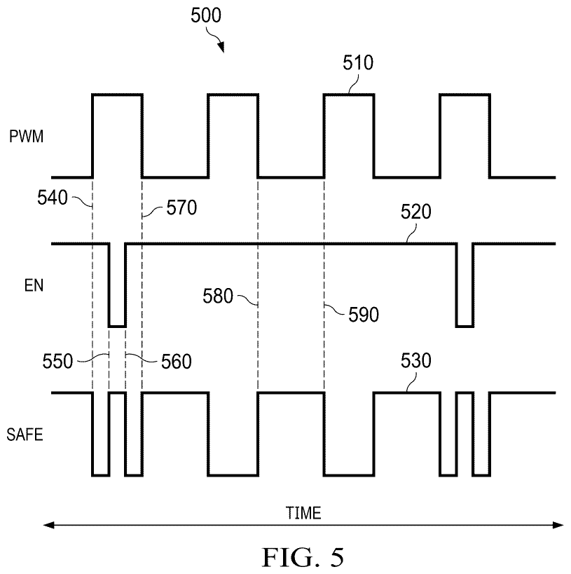

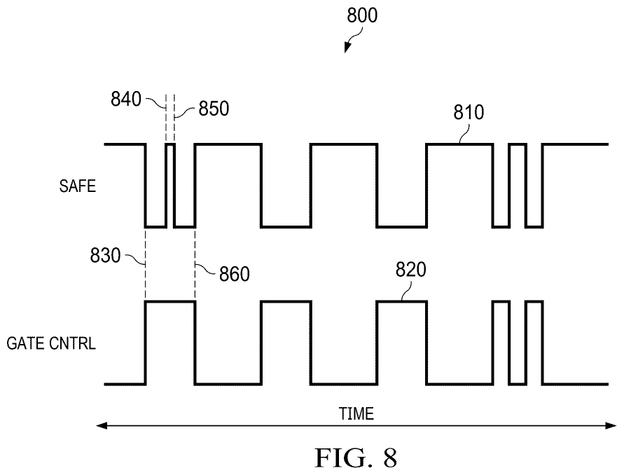

The current sense circuitry 180 has a first terminal and a second terminal. The first terminal of the current sense circuitry 180 is coupled to the charge injection circuitry 160. The second terminal of the current sense circuitry 180 is coupled to the output stage circuitry 130. In the example of FIG. 1, the current sense circuitry 180 is structured to generate a safe signal (SAFE), responsive to currents of the charge injection circuitry 160. The safe signal indicates a state of the isolated gate driver circuitry 145. An example of the safe signal is illustrated and described in connection with FIGS. 5 and 8, below. An example of the current sense circuitry 180 is illustrated and described in connection with FIG. 2, below.

In example operation, the programmable circuitry 105 generates a first PWM signal (PWM_{U}), a second PWM signal (PWM_{V}), and a third PWM signal (PWM_{W}) having different phases. The programmable circuitry 105 supplies one of the PWM signals to each of the driver circuitry 110, 115, 120. The different phases of the PWM signals sequence the supply of power by the driver circuitry 110, 115, 120 to rotate the motor 125. In the example of FIG. 1, the control system 100 is structured as a three-phase motor control system, which uses three signals to drive the motor 125. Alternatively, the control system 100 may be modified to support any number of phases to control a motor.

In example operation, the isolated gate driver circuitry 145 receives a PWM signal from the programmable circuitry 105. The logic circuitry 155 logically combines the enable signal and the PWM signal to control the charge injection circuitry 160. In some examples, the logic circuitry 155 generates a logically combined signal and an inverted logically combined signal. In such examples, the logic circuitry 155 uses the logically combined signals to control the charge injection circuitry 160. The charge injection circuitry 160 supplies current to the transformer circuitry 165 based on the state of the logically combined signals. For example, in response to the PWM signal and the enable signal being at a logical high the charge injection circuitry 160 supplies current to the transformer circuitry 165. The transformer circuitry 165 generates an oscillating current that traverses an isolation barrier. Such isolation is referred to as galvanic isolation. The receiver circuitry 170 receives the oscillating current after traversing the isolation barrier. Advantageously, the transformer circuitry 165 isolates voltages of the charge injection circuitry 160 and the programmable circuitry 105 from voltages of the receiver circuitry 170 and the transistors 135, 140. Advantageously, the transformer circuitry 165 allows the isolated gate driver circuitry 145 to generate control signals having relatively high voltages based on signals having relatively low voltages.

In example operation, the current sense circuitry 180 monitors the charge injection circuitry 160. The current sense circuitry 180 generates the safe signal based on currents being supplied to the transformer circuitry 165 by the charge injection circuitry 160. For example, the current sense circuitry 180 sets the safe signal to a logical low responsive to sensing a current is being supplied by the charge injection circuitry 160. In such examples, the current sense circuitry 180 sets the safe signal to a logical high responsive to sensing a current is not being supplied by the charge injection circuitry 160. Alternatively, in other examples, the safe signal may be an actively low signal (nSAFE). The output stage circuitry 130 logically combines safe signals from the driver circuitry 110, 115, 120 to generate a system fault signal. The programmable circuitry 105 determines the control system 100 is safely operating responsive to a comparison of the system fault signal to the PWM signals. In such example operations, the programmable circuitry 105 detects an unsafe condition of the control system 100 responsive to the PWM signals matching the safe signal. Further example operations of the control system 100 are further illustrated and described in connection with FIGS. 4 and 7, below.

FIG. 2 is a schematic diagram of example isolated gate driver circuitry 200, which is an example of the isolated gate driver circuitry 145, 150 of FIG. 1. In the example of FIG. 2, the isolated gate driver circuitry 200 includes logic circuitry 202, charge injection circuitry 204, transformer circuitry 206, and current sense circuitry 208. The example logic circuitry 202 of FIG. 2 includes an example logic device 210, a first example inverter 212, and a second example inverter 214. The example charge injection circuitry 204 of FIG. 2 includes example current source circuitry 216, a first example transistor 218, a second example transistor 220, a third example transistor 222, a fourth example transistor 224, a fifth example transistor 226, a sixth example transistor 228, a seventh example transistor 230, an example transmission gate 232, an eighth example transistor 234, a ninth example transistor 236, a tenth example transistor 238, an eleventh example transistor 240, a twelfth example transistor 242, a thirteenth example transistor 244, and a fourteenth example transistor 246. The example transformer circuitry 206 of FIG. 2 includes a first example capacitor 248, a second example capacitor 250, a first example inductor 252, an example isolation barrier 254, a second example inductor 256, a third example capacitor 258, and a fourth example capacitor 260. The example current sense circuitry 208 of FIG. 2 includes an example transistor 262, an example resistor 264, example comparator circuitry 266, example level shifter circuitry 268, example buffer circuitry 270, and an example inverter 272.

The isolated gate driver circuitry 200 has a first input terminal, a second input terminal, a first output terminal, a second output terminal, and a third output terminal. The first input terminal of the isolated gate driver circuitry 200 is structured to be coupled to the programmable circuitry 105 of FIG. 1, which supplies a PWM signal (PWM). The second input terminal of the isolated gate driver circuitry 200 is structured to be coupled to the programmable circuitry 105 of FIG. 1, which supplies an enable signal (EN). The first and second output terminals of the isolated gate driver circuitry 200 are structured to be coupled to the receiver circuitry 170 of FIG. 1, which receives an oscillating current. The third output terminal of the isolated gate driver circuitry 200 is structured to be coupled to the output stage circuitry 130 of FIG. 1, which receives a safe signal (SAFE). Examples of the inputs and outputs of the isolated gate driver circuitry 200 are illustrated and described in connection with FIG. 5, below. Example operations of the isolated gate driver circuitry 200 are illustrated and described in connection with FIG. 4, below.

The logic circuitry 202 has a first terminal, a second terminal, a third terminal, and a fourth terminal. The first terminal of the logic circuitry 202 is coupled to the first input terminal of the isolated gate driver circuitry 200, which supplies the PWM signal. The second terminal of the logic circuitry 202 is coupled to the second input terminal of the isolated gate driver circuitry 200, which supplies the enable signal. The third and fourth terminals of the logic circuitry 202 are coupled to the charge injection circuitry 204. In the example of FIG. 2, the logic circuitry 202 is structured to supply a combined control signal (InZ) and an inverted combined control signal (InZZ) to the charge injection circuitry 204. The logic circuitry 202 is an example of the logic circuitry 155 of FIG. 1.

The charge injection circuitry 204 has a first terminal, a second terminal, a third terminal, a fourth terminal, and a fifth terminal. The first and second terminals of the charge injection circuitry 204 are coupled to the logic circuitry 202, which supplies the combined control signal and the inverted combined control signal. The third and fourth terminals of the charge injection circuitry 204 are coupled to the transformer circuitry 206. The fifth terminal of the charge injection circuitry 204 is coupled to the current sense circuitry 208. The charge injection circuitry 204 is an example of the charge injection circuitry 160 of FIG. 1.

The transformer circuitry 206 has a first terminal, a second terminal, a third terminal, and a fourth terminal. The first and second terminals of the transformer circuitry 206 are coupled to the charge injection circuitry 204. The third and fourth terminals of the transformer circuitry 206 are coupled to the first and second output terminals of the isolated gate driver circuitry 200, which are structured to supply oscillating currents to the receiver circuitry 170. The transformer circuitry 206 is an example of the transformer circuitry 165 of FIG. 1.

The current sense circuitry 208 has a first terminal and a second terminal. The first terminal of the current sense circuitry 208 is coupled to the charge injection circuitry 204. The second terminal of the current sense circuitry 208 is coupled to the third output terminal of the isolated gate driver circuitry 200, which supplies the safe signal to the output stage circuitry 130. The current sense circuitry 208 is an example of the current sense circuitry 180 of FIG. 1.

The logic device 210 has a first terminal, a second terminal, and a third terminal. The first terminal of the logic device 210 is coupled to the first input terminal of the isolated gate driver circuitry 200, which receives the PWM signal from the programmable circuitry 105. The second terminal of the logic device 210 is coupled to the second input terminal of the isolated gate driver circuitry 200, which receives the enable signal from the programmable circuitry 105. The third terminal of the logic device 210 is coupled to the inverter 212. In the example of FIG. 2, the logic device 210 is an AND gate. In other examples, the logic device 210 may be implemented using one or more alternative logic devices.

The inverter 212 has a first terminal and a second terminal. The first terminal of the inverter 212 is coupled to the logic device 210. The second terminal of the inverter 212 is coupled to the charge injection circuitry 204 and the inverter 214. In the example of FIG. 2, the inverter 212 generates the combined control signal based on an output of the logic device 210.

The inverter 214 has a first terminal and a second terminal. The first terminal of the inverter 214 is coupled to the charge injection circuitry 204 and the inverter 212. The second terminal of the inverter 214 is coupled to the charge injection circuitry 204. In the example of FIG. 2, the inverter 214 generates the inverted combined control signal based on the combined control signal from the inverter 212.

The current source circuitry 216 has a first terminal and a second terminal. The first terminal of the current source circuitry 216 is coupled to a supply terminal, which supplies a supply voltage (VDD). The second terminal of the current source circuitry 216 is coupled to the transistors 218, 220, 222.

The transistor 218 has a first terminal, a second terminal, and a control terminal. The first and control terminals of the transistor 218 are coupled to the current source circuitry 216 and the transistors 220, 222. The second terminal of the transistor 218 is coupled to a common terminal, which supplies a common potential (e.g., ground, AVSS, etc.).

The transistor 220 has a first terminal, a second terminal, and a control terminal. The first terminal of the transistor 220 is coupled to the current source circuitry 216 and the transistors 218, 222. The second terminal of the transistor 220 is coupled to the common terminal, which supplies the common potential. The control terminal of the transistor 220 is coupled to the first output terminal of the logic circuitry 202, which supplies the combined control signal.

The transistor 222 has a first terminal, a second terminal, and a control terminal. The first terminal of the transistor 222 is coupled to the transistor 224. The second terminal of the transistor 222 is coupled to the common terminal, which supplies the common potential. The control terminal of the transistor 222 is coupled to the current source circuitry 216 and the transistors 218, 220.

The transistor 224 has a first terminal, a second terminal, and a control terminal. The first terminal of the transistor 224 is coupled to the current sense circuitry 208 and the transistors 226, 228, 242. The second terminal of the transistor 224 is coupled to the transistor 222. The control terminal of the transistor 224 is coupled to the second output terminal of the logic circuitry 202, which supplies the inverted combined control signal.

The transistor 226 has a first terminal, a second terminal, and a control terminal. The first terminal of the transistor 226 is coupled to the supply terminal, which supplies the supply voltage. The second terminal of the transistor 226 is coupled to the current sense circuitry 208 and the transistors 224, 228, 242. The control terminal of the transistor 226 is coupled to the second output terminal of the logic circuitry 202, which supplies the inverted combined control signal.

The transistor 228 has a first terminal, a second terminal, and a control terminal. The first terminal of the transistor 228 is coupled to the supply terminal, which supplies the supply voltage. The second terminal of the transistor 228 is coupled to the current sense circuitry 208 and the transistors 224, 226, 242. The control terminal of the transistor 228 is coupled to the transistors 230, 236 and the transmission gate 232.

The transistor 230 has a first terminal, a second terminal, and a control terminal. The first terminal of the transistor 230 is coupled to the supply terminal, which supplies the supply voltage. The second terminal of the transistor 230 is coupled to the transistors 228, 236 and the transmission gate 232. The control terminal of the transistor 230 is coupled to the second output terminal of the logic circuitry 202, which supplies the inverted combined control signal.

The transmission gate 232 has a first terminal, a second terminal, a first control terminal, and a second control terminal. The first terminal of the transmission gate 232 is coupled to the transistors 228, 230, 236. The second terminal of the transmission gate 232 is coupled to the transistors 234, 236, 238, 240. The first control terminal of the transmission gate 232 is coupled to the first output terminal of the logic circuitry 202, which supplies the combined control signal. The second control terminal of the transmission gate 232 is coupled to the second output terminal of the logic circuitry 202, which supplies the inverted combined control signal. In some examples, the transmission gate 232 is illustrated or described as a pair of transistors structured to control a direction of current.

The transistor 234 has a first terminal, a second terminal, and a control terminal. The first terminal of the transistor 234 is coupled to the transmission gate 232 and the transistors 236, 238, 240. The second terminal of the transistor 234 is coupled to the common terminal, which supplies the common potential. The control terminal of the transistor 234 is coupled to the first output terminal of the logic circuitry 202, which supplies the combined control signal.

The transistor 236 has a first terminal, a second terminal, and a control terminal. The first terminal of the transistor 236 is coupled to the supply terminal, which supplies the supply voltage. The second terminal of the transistor 236 is coupled to the transmission gate 232 and the transistors 234, 238, 240. The control terminal of the transistor 236 is coupled to the transistors 228, 230 and the transmission gate 232.

The transistor 238 has a first terminal, a second terminal, and a control terminal. The first terminal of the transistor 238 is coupled to the transmission gate 232 and the transistors 234, 236, 240. The second terminal of the transistor 238 is coupled to the transformer circuitry 206 and the transistors 240, 244, 246. The control terminal of the transistor 238 is coupled to the transformer circuitry 206 and the transistors 240, 244, 246.

The transistor 240 has a first terminal, a second terminal, and a control terminal. The first terminal of the transistor 240 is coupled to the transmission gate 232 and the transistors 234, 236, 238. The second terminal of the transistor 240 is coupled to the transformer circuitry 206 and the transistors 238, 244, 246. The control terminal of the transistor 240 is coupled to the transformer circuitry 206 and the transistors 238, 244, 246.

The transistor 242 has a first terminal, a second terminal, and a control terminal. The first terminal of the transistor 242 is coupled to the supply terminal, which supplies the supply voltage. The second terminal of the transistor 242 is coupled to the transistors 244, 246. The control terminal of the transistor 242 is coupled to the current sense circuitry 208 and the transistors 224, 226, 228.

The transistor 244 has a first terminal, a second terminal, and a control terminal. The first terminal of the transistor 244 is coupled to the transistors 242, 246. The second terminal of the transistor 244 is coupled to the transformer circuitry 206 and the transistors 238, 240, 246. The control terminal of the transistor 244 is coupled to the transformer circuitry 206 and the transistors 238, 240, 246.

The transistor 246 has a first terminal, a second terminal, and a control terminal. The first terminal of the transistor 246 is coupled to the transistors 242, 244. The second terminal of the transistor 246 is coupled to the transformer circuitry 206 and the transistors 238, 240, 244. The control terminal of the transistor 246 is coupled to the transformer circuitry 206 and the transistors 238, 240, 244.

The capacitor 248 has a first terminal and a second terminal. The first terminal of the capacitor 248 is coupled to the transistors 238, 240, 244, 246 and the inductor 252. The second terminal of the capacitor 248 is coupled to the capacitor 250 and the common terminal, which supplies the common potential.

The capacitor 250 has a first terminal and a second terminal. The first terminal of the capacitor 250 is coupled to the transistors 238, 240, 244, 246 and the inductor 252. The second terminal of the capacitor 250 is coupled to the common terminal, which supplies the common potential.

The inductor 252 has a first terminal and a second terminal. The first terminal of the inductor 252 is coupled to the transistors 238, 240, 244, 246 and the capacitor 248. The second terminal of the inductor 252 is coupled to the transistors 238, 240, 244, 246 and the capacitor 250. The inductor 252 is magnetically coupled to the inductor 256 across the isolation barrier 254. In the example of FIG. 2, the capacitors 248, 250 and the inductor 252 form first inductor-capacitor (LC) circuitry, which may be referred to as an LC tank. In example operations, current oscillating between the capacitors 248, 250 and the inductor 252 of the LC circuitry generate a sinusoidal signal, which traverses the isolation barrier 254. In such example operations, the LC circuitry begins to generate the sinusoidal signal responsive to current from the charge injection circuitry 160, 204.

The isolation barrier 254 is coupled between the inductors 252, 256. The isolation barrier 254 is an illustrative representation of a separation of the inductors 252, 256. In the example of FIG. 2, the circuitry above the line representing the isolation barrier 254 is considered as a primary side and the circuitry below the isolation barrier 254 is considered as a secondary side. In some examples, the isolation barrier 254 is illustrated as a part of a transformer (such as a shared core) that the inductors 252, 256 are wound around.

The inductor 256 has a first terminal and a second terminal. The first terminal of the inductor 256 is coupled to the capacitor 258 and the first output terminal of the isolated gate driver circuitry 200, which is structured to be coupled to the receiver circuitry 170. The second terminal of the inductor 256 is coupled to the capacitor 260 and the second output terminal of the isolated gate driver circuitry 200, which is structured to be coupled to the receiver circuitry 170. The inductor 256 is magnetically coupled to the inductor 252.

The capacitor 258 has a first terminal and a second terminal. The first terminal of the capacitor 258 is coupled to the inductor 256 and the first output terminal of the isolated gate driver circuitry 200, which is structured to be coupled to the receiver circuitry 170. The second terminal of the capacitor 258 is coupled to the capacitor 260 and the common terminal, which supplies the common potential.

The capacitor 260 has a first terminal and a second terminal. The first terminal of the capacitor 260 is coupled to the inductor 256 and the second output terminal of the isolated gate driver circuitry 200, which is structured to be coupled to the receiver circuitry 170. The second terminal of the capacitor 260 is coupled to the capacitor 258 and the common terminal, which supplies the common potential. In the example of FIG. 2, the inductor 256 and the capacitors 258, 260 form second LC circuitry, which may be referred to as an LC tank. In example operations, current oscillates between the inductor 256 and the capacitors 258, 260 responsive to the inductor 252 of the first LC circuitry generating a sinusoidal signal. In such example operations, the sinusoidal signal traverses the isolation barrier 254 to induce current in the inductor 256, which generates a secondary sinusoidal signal in the inductor 256 and the capacitors 258, 260.

The transistor 262 has a first terminal, a second terminal, and a control terminal. The first terminal of the transistor 262 is coupled to the supply terminal, which supplies the supply voltage. The second terminal of the transistor 262 is coupled to the resistor 264 and the comparator circuitry 266. The control terminal of the transistor 262 is coupled to the transistors 224, 226, 228, 242 of the charge injection circuitry 204.

The resistor 264 has a first terminal and a second terminal. The first terminal of the resistor 264 is coupled to the transistor 262 and the comparator circuitry 266. The second terminal of the resistor 264 is coupled to the common terminal, which supplies the common potential.

The comparator circuitry 266 has a first terminal and a second terminal. The first terminal of the comparator circuitry 266 is coupled to the transistor 262 and the resistor 264. The second terminal of the comparator circuitry 266 is coupled to the level shifter circuitry 268. In some examples, the comparator circuitry 266 is illustrated or described as amplifier circuitry.

The level shifter circuitry 268 has a first terminal and a second terminal. The first terminal of the level shifter circuitry 268 is coupled to the comparator circuitry 266. The second terminal of the level shifter circuitry 268 is coupled to the buffer circuitry 270.

The buffer circuitry 270 has a first terminal and a second terminal. The first terminal of the buffer circuitry 270 is coupled to the level shifter circuitry 268. The second terminal of the buffer circuitry 270 is coupled to the inverter 272.

The inverter 272 has a first terminal and a second terminal. The first terminal of the inverter 272 is coupled to the buffer circuitry 270. The second terminal of the inverter 272 is coupled to the third output terminal of the isolated gate driver circuitry 200, which is structured to be coupled to the output stage circuitry 130. Alternatively, in some examples, the current sense circuitry 208 may be modified to remove or replace the inverter 272. In such examples, the current sense circuitry 208 produces an active low signal.

In the example of FIG. 2, the transistors 218, 220, 222, 224, 234, 238, 240 are n-channel MOSFETs. Alternatively, the transistors 218, 220, 222, 224, 234, 238, 240 may be n-channel FETs, n-channel IGBTs, n-channel JFETs, NPN BJTs or, with slight modifications, p-type equivalent devices. In the example of FIG. 2, the transistors 226, 228, 230, 236, 242, 244, 246, 262 are p-channel MOSFETs. Alternatively, the transistors 226, 228, 230, 236, 242, 244, 246, 262 may be p-channel FETs, p-channel IGBTs, p-channel JFETs, PNP BJTs, or, with slight modifications, N-type equivalent devices. The transistors 218, 220, 222, 224, 226, 228, 230, 234, 236, 238, 240, 242, 244, 246 262 may be depletion mode devices, drain-extended devices, enhancement mode devices, natural transistors, or other type of device structure transistors. Furthermore, the transistors 218, 220, 222, 224, 226, 228, 230, 234, 236, 238, 240, 242, 244, 246 262 may be implemented in/over a silicon substrate (Si), a silicon carbide substrate (SiC), a gallium nitride substrate (GaN) or a gallium arsenide substrate (GaAs).

FIG. 3A is a schematic diagram of an example control system 300, which is another example of the control system 100 of FIG. 1. In the example of FIG. 3A, the control system 300 includes first driver circuitry 305, second driver circuitry 310, third driver circuitry 315, and output stage circuitry 320. The example output stage circuitry 320 of FIG. 3A includes an example logic device 325.

The control system 300 has a first input terminal, a second input terminal, a third input terminal, a first output terminal, a second output terminal, a third output terminal, and a fourth output terminal. The first, second, and third input terminals of the control system 300 are structured to be coupled to the programmable circuitry 105 of FIG. 1, which supplies a first PWM signal (PWM_{U}), a second PWM signal (PWM_{V}), and a third PWM signal (PWM_{W}). The first, second, and third output terminals of the control system 300 are structured to be coupled to the motor 125 of FIG. 1. The fourth output terminal of the control system 300 is structured to be coupled to the programmable circuitry 105, which receives a system fault signal (nFAULT). The system fault signal represents a state of the driver circuitry 305, 310, 315. For example, the system fault signal is cleared responsive to one or more of the driver circuitry 305, 310, 315 supplying current across the transformer circuitry 165, 206.

The driver circuitry 305 has an input terminal, a first output terminal, and a second output terminal. The input terminal of the driver circuitry 305 is coupled to the first input terminal of the control system 300, which supplies the first PWM signal from the programmable circuitry 105. The first output terminal of the driver circuitry 305 is coupled to the motor 125. The second output terminal of the driver circuitry 305 is coupled to the output stage circuitry 320. The driver circuitry 305 is an example of the driver circuitry 110 of FIG. 1.

The driver circuitry 310 has an input terminal, a first output terminal, and a second output terminal. The input terminal of the driver circuitry 310 is coupled to the second input terminal of the control system 300, which supplies the second PWM signal from the programmable circuitry 105. The first output terminal of the driver circuitry 310 is coupled to the motor 125. The second output terminal of the driver circuitry 310 is coupled to the output stage circuitry 320. The driver circuitry 310 is an example of the driver circuitry 115 of FIG. 1.

The driver circuitry 315 has an input terminal, a first output terminal, and a second output terminal. The input terminal of the driver circuitry 315 is coupled to the first input terminal of the control system 300, which supplies the third PWM signal from the programmable circuitry 105. The first output terminal of the driver circuitry 315 is coupled to the motor 125. The second output terminal of the driver circuitry 315 is coupled to the output stage circuitry 320. The driver circuitry 315 is an example of the driver circuitry 120 of FIG. 1.

The output stage circuitry 320 has a first input terminal, a second input terminal, a third input terminal, and an output terminal. The first input terminal of the output stage circuitry 320 is coupled to the driver circuitry 305, which supplies a first safe signal (SAFE_{U}). The safe signal represents a state of the driver circuitry 305. In a first state, the driver circuitry 305 is supplying current to the transformer circuitry 165, 206. In a second state, the driver circuitry 305 is not supplying current to the transformer circuitry 165, 206. The second input terminal of the output stage circuitry 320 is coupled to the driver circuitry 310, which supplies a second safe signal (SAFE_{V}), which represents the state of the driver circuitry 310. The third input terminal of the output stage circuitry 320 is coupled to the driver circuitry 315, which supplies a third safe signal (SAFE_{W}), which represents the state of the driver circuitry 315. The output terminal of the output stage circuitry 320 is coupled to the fourth output terminal of the control system 300, which supplies the system fault signal to the programmable circuitry 105.

The logic device 325 has a first input terminal, a second input terminal, a third input terminal, and an output terminal. The first input terminal of the logic device 325 is coupled to the driver circuitry 305, which supplies the first safe signal. The second input terminal of the logic device 325 is coupled to the driver circuitry 310, which supplies the second safe signal. The third input terminal of the logic device 325 is coupled to the driver circuitry 315, which supplies the third safe signal. The output terminal of the logic device 325 is coupled to the fourth output terminal of the control system 300, which supplies the system fault signal to the programmable circuitry 105. In the example of FIG. 3A, the logic device 325 is an AND gate. Alternatively, the logic device 325 may be an alternative type of logic device or combination of logic devices.

FIG. 3B is a schematic diagram of an example control system 330, which is another example of the control systems 100, 300 of FIGS. 1 and 3A. In the example of FIG. 3B, the control system 330 includes first driver circuitry 335, second driver circuitry 340, third driver circuitry 345, and output stage circuitry 350. The example output stage circuitry 350 of FIG. 3B includes an example resistor 355.

The control system 330 has a first input terminal, a second input terminal, a third input terminal, a first output terminal, a second output terminal, a third output terminal, and a fourth output terminal. The first, second, and third input terminals of the control system 330 are structured to be coupled to the programmable circuitry 105 of FIG. 1, which supplies a first PWM signal (PWM_{U}), a second PWM signal (PWM_{V}), and a third PWM signal (PWM_{W}). The first, second, and third output terminals of the control system 330 are structured to be coupled to the motor 125 of FIG. 1. The fourth output terminal of the control system 330 is structured to be coupled to the programmable circuitry 105, which receives a system fault signal (nFAULT). The system fault signal represents a state of the driver circuitry 335, 340, 345. For example, the system fault signal is cleared responsive to one or more of the driver circuitry 335, 340, 345 supplying current across the transformer circuitry 165, 206.

The driver circuitry 335 has an input terminal, a first output terminal, and a second output terminal. The input terminal of the driver circuitry 335 is coupled to the first input terminal of the control system 330, which supplies the first PWM signal from the programmable circuitry 105. The first output terminal of the driver circuitry 335 is coupled to the motor 125. The second output terminal of the driver circuitry 335 is coupled to the driver circuitry 340, 345 and the output stage circuitry 350. The driver circuitry 335 is an example of the driver circuitry 110 of FIG. 1.

The driver circuitry 340 has an input terminal, a first output terminal, and a second output terminal. The input terminal of the driver circuitry 340 is coupled to the second input terminal of the control system 330, which supplies the second PWM signal from the programmable circuitry 105. The first output terminal of the driver circuitry 340 is coupled to the motor 125. The second output terminal of the driver circuitry 340 is coupled to the driver circuitry 335, 345 and the output stage circuitry 350. The driver circuitry 340 is an example of the driver circuitry 115 of FIG. 1.

The driver circuitry 345 has an input terminal, a first output terminal, and a second output terminal. The input terminal of the driver circuitry 345 is coupled to the first input terminal of the control system 330, which supplies the third PWM signal from the programmable circuitry 105. The first output terminal of the driver circuitry 345 is coupled to the motor 125. The second output terminal of the driver circuitry 345 is coupled to the driver circuitry 335, 340 and the output stage circuitry 350. The driver circuitry 345 is an example of the driver circuitry 120 of FIG. 1.

The output stage circuitry 350 has an input terminal and an output terminal. The input terminal of the output stage circuitry 350 is coupled to the driver circuitry 335, 340, 345, which supply a first safe signal (SAFE_{U}), a second safe signal (SAFE_{V}), and a third safe signal (SAFE_{W}). The safe signal represents the state of the driver circuitry 335. In the first state, the driver circuitry 335 is supplying current to the transformer circuitry 165, 206. In a second state, the driver circuitry 335 is not supplying current to the transformer circuitry 165, 206. The output terminal of the output stage circuitry 350 is coupled to the fourth output terminal of the control system 330, which supplies the system fault signal to the programmable circuitry 105.

The resistor 355 has a first terminal and a second terminal. The first terminal of the resistor 355 is coupled to the supply terminal, which supplies the supply voltage. The second terminal of the resistor 355 is coupled to the driver circuitry 335, 340, 345, which supply the first, second, and third safe signals, and the fourth output terminal of the control system 330. In the example of FIG. 3B, the resistor 355 is a pull-up resistor.

FIG. 4 is a flowchart representative of example machine-readable instructions or example operations 400 that may be at least one of executed, instantiated, or preformed using example implementations of the isolated gate driver circuitry 145, 200 of FIGS. 1 and 2, the programmable circuitry 105 of FIG. 1, or more generally, the control system 100, 300, 330 of FIGS. 1, 3A, and 3B. In the example of FIG. 4, the operations 400 are illustrated and described in relation to the SAFE signal being an active high signal. Alternatively, the operations 400 may be modified to support an active low signal.

The example operations 400 of FIG. 4 begin at Block 405, at which the programmable circuitry 105 generates a PWM signal. (Block 405). In example operations, the programmable circuitry 105 generates a PWM signal using a first voltage to represent a logical one and a second voltage to represent a logical zero. In such example operations, the programmable circuitry 105 sets a duty cycle of the PWM signal based on a duration of time at which the driver circuitry 110 is to supply electrical power to the motor 125. An example of the PWM signal is illustrated and described in connection with FIG. 5, below. In some examples, the programmable circuitry 105 also generates an enable signal, which further controls the driver circuitry 110. In some such examples, the enable signal is a redundant signal that improves the likelihood of accurately supplying power to the motor 125. An example of the enable signal is illustrated and described in connection with FIG. 5, below.

The logic circuitry 155, 202 of FIGS. 1 and 2 determines if the PWM signal is a logic one. (Block 410). In example operations, the logic circuitry 155, 202 generates a combined control signal and an inverted responsive to at least one of the PWM signal and the enable signal. In such example operations, the logic circuitry 155, 202 logically combines the PWM signal and the enable signal. For example, the logic device 210 of FIG. 2 logically ANDs the PWM and enable signals from the programmable circuitry 105. In such examples, the inverters 212, 214 of FIG. 2 generate the combined control signal and inverted control signal by inverting the output of the logic device 210.

If the logic circuitry 155, 202 determines that the PWM signal is a logic one (e.g., Block 410 returns a result of YES), the charge injection circuitry 160, 204 of FIGS. 1 and 2 injects current into an inductor-capacitor circuitry. (Block 415). In example operations, the charge injection circuitry 160, 204 begins to conduct current responsive to the combined control signal and inverted combined control signal from the logic circuitry 155, 202. For example, the transistors 222, 224, 226 of FIG. 2 form a first current path responsive to the combined control signal being a logic zero and the inverted combined control signal being a logic one. In such examples, the transistor 222 mirrors the current through the transistor 218 of FIG. 2, which pulls down the control terminal of the transistors 242, 262 of FIG. 2. The transistors 242, 262 begin to conduct current responsive to the currents of the transistors 222, 224 pulling the voltage at the control terminals of the transistors 242, 262 towards the common potential. In such example operations, the transistors 238, 240, 244, 246 of FIG. 2 supply current to the capacitors 248, 250 and the inductor 252, which form the primary side LC circuitry.

The transformer circuitry 165, 206 of FIGS. 1 and 2 generate a sinusoidal signal using the inductor-capacitor circuit. (Block 420). In example operations, the transformer circuitry 165, 206 receives current from the transistors 238, 240, 244, 246 responsive to the combined control signal and the inverted combined control signal turning on the transistors 236, 242. In some examples, the capacitors 248, 250 and the inductor 252 generate a sinusoidal signal by driving the cross coupled control terminals of the transistors 238, 240, 244, 246. In such examples, current from the transistors 238, 240, 244, 246 compensate the capacitors 248, 250 and the inductor 252 for charge lost to non-ideal components, such as a parasitic resistance. In such example operations, the capacitors 248, 250 and the inductor 252 generate the sinusoidal signal responsive to the oscillation of current between the capacitors 248, 250 and the inductor 252.

The transformer circuitry 165, 206 transmits the sinusoidal signal across an isolation barrier. (Block 425). In example operation, the inductor 252 is magnetically coupled to the inductor 256 of FIG. 2 across the isolation barrier 254 of FIG. 2. In some examples, the inductors 252, 256 are magnetically coupled by a core. In such examples, the inductor 252 generates a magnetic field responsive to the alternating currents of the sinusoidal signal, which induces current in the inductor 256. In such example operations, the inductor 256 and the capacitors 258, 260 produce an induced sinusoidal signal responsive to the inductor 252 inducing a current in the inductor 256. The receiver circuitry 170 of FIG. 1 determines a logic one of the PWM signal responsive to receiving the induced sinusoidal signal.

The current sense circuitry 180, 208 of FIGS. 1 and 2 determines if current is being injected into the inductor capacitor circuit. (Block 430). In example operations, the transistors 244, 246 inject current into the LC circuitry formed by the capacitors 248, 250 and the inductor 252 responsive to the transistor 242 conducting current. In such example operations, the transistor 262 mirrors the current through the transistor 242 responsive to the control terminals of the transistors 242, 262 being coupled. Advantageously, the transistor 262 of the current sense circuitry 208 conducts current responsive to the charge injection circuitry 204 structuring the transistor 242 to conduct current.

If the current sense circuitry 180, 208 determines that current is being injected into the inductor capacitor circuit (e.g., Block 430 returns a result of YES), the current sense circuitry 180, 208 sets a safe signal to a logic zero. (Block 435). In example operations, the resistor 264 of FIG. 2 generates a reference voltage responsive to the charge injection circuitry 204 structuring the transistor 262 to conduct current. In such example operations, the comparator circuitry 266 of FIG. 2 generates a logic one responsive to detecting the reference voltage of the resistor 264. The level shifter circuitry 268 of FIG. 2 converts voltages of the comparator circuitry 266 to logic levels of the programmable circuitry 105. For example, under the condition of the supply voltage being twelve volts and the programmable circuitry 105 being structured for five-volt signals, the level shifter circuitry 268 converts the voltages of the comparator circuitry 266 for the programmable circuitry 105. The buffer circuitry 270 of FIG. 2 buffers signals from the level shifter circuitry 268 to increase signal strength. The inverter 272 of FIG. 2 generates the safe signal (SAFE) by inverting the logical state of the output of the buffer circuitry 270. In some examples, the current sense circuitry 180, 208 sets the safe signal to a logic zero responsive to the transistor 262 conducting current.

If the current sense circuitry 180, 208 determines that current is not being injected into the inductor capacitor circuit (e.g., Block 430 returns a result of NO), the current sense circuitry 180, 208 sets a safe signal to a logic one. (Block 440). In example operations, the resistor 264 sets the input of the comparator circuitry 266 to the common potential responsive to the charge injection circuitry 204 failing to structure the transistor 262 to conduct current. In such example operations, the level shifter circuitry 268 converts voltages of the comparator circuitry 266 to logic levels of the programmable circuitry 105. In some examples, the current sense circuitry 180, 208 sets the safe signal to a logic one responsive to the resistor 264 setting the input of the comparator circuitry 266 to the common potential.

The programmable circuitry 105 determines if the safe signal is opposite of the PWM signal. (Block 445). In example operations, the programmable circuitry 105 determines if the isolated gate driver circuitry 145, 200 is safely operating responsive to a comparison of the safe signal from the current sense circuitry 180, 208 to the PWM signal. In such example operations, the programmable circuitry 105 determines the isolated gate driver circuitry 145, 200 is safely operating responsive to the PWM signal having a logical state opposite of the logical state of the safe signal. In some examples, the output stage circuitry 130, 320, 350 of FIGS. 1, 3A, and 3B combines a plurality of safe signals from a plurality of instances of the isolated gate driver circuitry 145, 200. In such examples, the programmable circuitry 105 compares the system fault signal to one or more PWM signals to determine if all instances of the isolated gate driver circuitry 145, 200 are safely operating. In the example of FIG. 3A, the programmable circuitry 105 determines one or more of the driver circuitry 305, 310, 315 of FIG. 3A are not safely operating responsive to the system fault signal being a logic zero under the condition of all of the PWM signals being a logic zero. In such an example, the logic device 325 indicates that at least one safe signal from the driver circuitry 305, 310, 315 corresponds to current conduction. In the example of FIG. 3B, the resistor 355 of FIG. 3B allows any of the safe signals from the driver circuitry 335, 340, 345 to set the system fault signal.

If the programmable circuitry 105 determines that the safe signal is opposite of the PWM signal (e.g., Block 445 returns a result of YES), the programmable circuitry 105 verifies the accuracy of the SAFE signal. (Operations 700 of FIG. 7). In example operations, the programmable circuitry 105 supplies test pulses to the isolated gate driver circuitry 145, 200 to verify the accuracy of safe signals. For example, in response to the safe signal being a logic zero for an extended duration, the programmable circuitry 105 supplies a test pulse that would modify the state of the safe signal for the duration of the test pulse. In such examples, the deglitch circuitry 175 of FIG. 1 deglitches pulses from the output of the receiver circuitry 170 responsive to the duration of the test pulse being less than a minimum duration. Advantageously, the deglitch circuitry 175 allows the programmable circuitry 105 to test the state of the safe signal without impacting the control of the transistor 135.

If the programmable circuitry 105 determines that the safe signal is the same as the PWM signal (e.g., Block 445 returns a result of NO), the programmable circuitry 105 turns off driver circuitry. (Block 450). In example operations, the programmable circuitry 105 sets at least one of the PWM signal or the enable signal to a safe state responsive to a determination that the isolated gate driver circuitry 145, 200 is unintentionally conducting current. Control proceeds to end.

Example methods are described with reference to the flowchart illustrated in FIG. 4. However, many other methods of implementing the isolated gate driver circuitry 145, 200 of FIGS. 1 and 2, the programmable circuitry 105 of FIG. 1, or more generally, the control system 100, 300, 330 of FIGS. 1, 3A, and 3B may also be used in this description. For example, the order of execution of the blocks may be changed, or some of the blocks described may be changed, eliminated, or combined. Similarly, additional operations may be included in the manufacturing process before, in between, or after the blocks shown in the illustrated examples.

FIG. 5 is a timing diagram 500 of example operations of the isolated gate driver circuitry 145, 200 of FIGS. 1 and 2. In the example of FIG. 5, the timing diagram 500 illustrates an example PWM signal 510 (PWM), an example enable signal 520 (EN), and an example safe signal 530 (SAFE).

The PWM signal 510 represents a signal from the programmable circuitry 105 of FIG. 1 to control the supply of power from the driver circuitry 110, 115, 120. In example operation, the programmable circuitry 105 may modify the duty cycle of the PWM signal 510 to adjust the amount of electrical power the driver circuitry 110, 115, 120 supplies to the motor 125 of FIG. 1.

The enable signal 520 represents a signal from the programmable circuitry 105 to control the driver circuitry 110, 115, 120. The logic circuitry 155, 202 of FIGS. 1 and 2 allow the isolated gate driver circuitry 145, 200 to control the transistor 135 of FIG. 1 responsive to the enable signal 520 being set (e.g., a logic one, logical high, etc.).

The safe signal 530 represents a signal from the current sense circuitry 180, 208 of FIGS. 1 and 2. The safe signal 530 represents whether the charge injection circuitry 160, 204 is supplying current to the transformer circuitry 165, 206. The current sense circuitry 180, 208 clears the safe signal 530 responsive to the charge injection circuitry 160, 204 being structured to supply current to the transformer circuitry 165, 206.

At a first time 540, the logic circuitry 155, 202 structures the charge injection circuitry 160, 204 to supply current to the transformer circuitry 165, 206 responsive to the PWM signal 510 and the enable signal 520 being set. At the first time 540, the current sense circuitry 180, 208 clears the safe signal 530 responsive to the charge injection circuitry 160 204 being structured to supply current to the transformer circuitry 165, 206.

At a second time 550, the programmable circuitry 105 imitates an unsafe operating condition by clearing the enable signal 520. At the second time 550, the logic circuitry 155, 202 structures the charge injection circuitry 160, 204 to prevent a supply of current to the transformer circuitry 165, 206. At the second time 550, the current sense circuitry 180, 208 sets the safe signal 530 responsive to the charge injection circuitry 160, 204 being structured to prevent the flow of current. However, if at the second time 550, the transistor 242 of FIG. 2 continues to conduct current, the programmable circuitry 105 may detect a system fault responsive to the safe signal 530 remaining cleared.

At a third time 560, the logic circuitry 155, 202 structures the charge injection circuitry 160, 204 to supply current to the transformer circuitry 165, 206 responsive to the PWM signal 510 and the enable signal 520 being set. At the third time 560, the current sense circuitry 180, 208 clears the safe signal 530 responsive to the charge injection circuitry 160 204 being structured to supply current to the transformer circuitry 165, 206.

Advantageously, between the times 550, 560, the current sense circuitry 180, 208 generates a pulse on the safe signal 530 responsive to the pulse of the enable signal 520. In some examples, as further described below, the programmable circuitry 105 may test the accuracy of the safe signal 530 responsive to generating relatively short pulses, such as the pulse between the times 550, 560. Advantageously, testing the safe signal 530 using relatively short pulses allows the programmable circuitry 105 to detect and adverse state, such as a terminal of the charge injection circuitry 160, 204 or the current sense circuitry 180, 208 being pulled high or low.

At a fourth time 570, the logic circuitry 155, 202 structures the charge injection circuitry 160, 204 to prevent a supply of current to the transformer circuitry 165, 206 responsive to the PWM signal 510 being cleared. At the fourth time 570, the current sense circuitry 180, 208 sets the safe signal 530 responsive to the charge injection circuitry 160, 204 being structured to not supply a current to the transformer circuitry 165, 206.

At a fifth time 580, the logic circuitry 155, 202 structures the charge injection circuitry 160, 204 to supply current to the transformer circuitry 165, 206 responsive to the PWM signal 510 and the enable signal 520 being set. At the fifth time 580, the current sense circuitry 180, 208 clears the safe signal 530 responsive to the charge injection circuitry 160 204 being structured to supply current to the transformer circuitry 165, 206.

At a sixth time 590, the logic circuitry 155, 202 structures the charge injection circuitry 160, 204 to prevent a supply of current to the transformer circuitry 165, 206 responsive to the PWM signal 510 being cleared. At the sixth time 590, the current sense circuitry 180, 208 sets the safe signal 530 responsive to the charge injection circuitry 160, 204 being structured to not supply a current to the transformer circuitry 165, 206.

FIG. 6 is a block diagram of example programmable circuitry 600, which is an example implementation of the programmable circuitry 105 of FIG. 1 to sense the safe signal of the isolated gate driver circuitry 145, 200 of FIGS. 1 and 2. The programmable circuitry 600 may be instantiated (e.g., creating an instance of, bring into being for any length of time, materialize, implement, etc.) by programmable circuitry such as a Central Processor Unit (CPU) executing first instructions. Also or alternatively, the programmable circuitry 600 may be instantiated (e.g., creating an instance of, bring into being for any length of time, materialize, implement, etc.) by (i) an Application Specific Integrated Circuit (ASIC) or (ii) a Field Programmable Gate Array (FPGA) structured or configured in response to execution of second instructions to perform operations corresponding to the first instructions. Some or all of the circuitry of FIG. 6 may, thus, be instantiated at the same or different times. Some or all of the circuitry of FIG. 6 may be instantiated, for example, in one or more threads executing concurrently on hardware or in series on hardware. Moreover, in some examples, some or all of the circuitry of FIG. 6 may be implemented by microprocessor circuitry executing instructions or FPGA circuitry performing operations to implement one or more virtual machines or containers. In the example of FIG. 6, the programmable circuitry 600 includes safe timer circuitry 610, pulse generator circuitry 620, PWM source circuitry 630, a logic device 640, and safe monitor circuitry 650.

The programmable circuitry 600 has an input terminal, a first output terminal, and a second output terminal. The input terminal of the programmable circuitry 600 is structured to be coupled to the current sense circuitry 180, 208 of FIGS. 1 and 2, which supply the safe signal (e.g., the safe signal 530 of FIG. 5). In some examples, the input terminal of the programmable circuitry 600 is structured to be coupled to the output stage circuitry 130, 320, 350 of FIGS. 1, 3A, and 3B, which supply the system fault signal. In both examples, the input terminal of the programmable circuitry 600 receives a signal representing a safety state of the control systems 100, 300, 330 of FIGS. 1, 3A, and 3B. The first and second output terminals of the programmable circuitry 600 are structured to be coupled to the logic circuitry 155, 202 of FIGS. 1 and 2 or more generally the isolated gate driver circuitry 145, 200. The programmable circuitry 600 supplies the PWM signal (e.g., the PWM signal 510 of FIG. 5) at the first output terminal and the enable signal (e.g., the enable signal 520 of FIG. 5) at the second output terminal.

The safe timer circuitry 610 has a first terminal and a second terminal. The first terminal of the safe timer circuitry 610 is coupled to the safe monitor circuitry 650 and the input terminal of the programmable circuitry 600, which supplies the safe signal from the isolated gate driver circuitry 145, 200 or the output stage circuitry 130, 320, 350. The second terminal of the safe timer circuitry 610 is coupled to the pulse generator circuitry 620. In some examples, the safe timer circuitry 610 is instantiated by programmable circuitry executing safe timer instructions to perform operations such as those represented by the flowchart of FIG. 7.

The pulse generator circuitry 620 has a first terminal and a second terminal. The first terminal of the pulse generator circuitry 620 is coupled to the safe timer circuitry 610. The second terminal of the pulse generator circuitry 620 is coupled to the logic device 640. In some examples, the pulse generator circuitry 620 is instantiated by programmable circuitry executing pulse generator instructions to perform operations such as those represented by the flowchart of FIG. 7.

The PWM source circuitry 630 has a first terminal, a second terminal, and a third terminal. The first terminal of the PWM source circuitry 630 is coupled to the second output terminal of the programmable circuitry 600, which supplies the enable signal to the isolated gate driver circuitry 145, 200. The second terminal of the PWM source circuitry 630 is coupled to the logic device 640. The third terminal of the PWM source circuitry 630 is coupled to the safe monitor circuitry 650. In some examples, the PWM source circuitry 630 is instantiated by programmable circuitry executing PWM source instructions to perform operations such as those represented by the flowchart of FIG. 7.

The logic device 640 has a first input terminal, a second input terminal, and an output terminal. The first input terminal of the logic device 640 is coupled to the pulse generator circuitry 620. The second input terminal of the logic device 640 is coupled to the PWM source circuitry 630. The output terminal of the logic device 640 is coupled to the safe monitor circuitry 650 and the first output terminal of the programmable circuitry 600, which supplies the PWM signal to the isolated gate driver circuitry 145, 200. In the example of FIG. 6, the logic device 640 is an AND gate having an inverting input. In some examples, the logic device 640 may be replaced with alternative type of logic device.

The safe monitor circuitry 650 has a first terminal, a second terminal, and a third terminal. The first terminal of the safe monitor circuitry 650 is coupled to the safe timer circuitry 610 and the input terminal of the programmable circuitry 600, which receives the safe signal from the isolated gate driver circuitry 145, 200. The second terminal of the safe monitor circuitry 650 is coupled to the PWM source circuitry 630. The third terminal of the safe monitor circuitry 650 is coupled to the logic device 640 and the first output terminal of the programmable circuitry 600, which supplies the PWM signal to the isolated gate driver circuitry 145, 200. In some examples, the safe monitor circuitry 650 is instantiated by programmable circuitry executing safe monitor instructions to perform operations such as those represented by the flowchart of FIG. 7.

FIG. 7 is a flowchart representative of example machine-readable instructions or example operations 700 that may be at least one of executed, instantiated, or performed using an example implementation of the programmable circuitry 105, 600 of FIGS. 1 and 6 to deglitch the safety state of the isolated gate driver circuitry 145, 200 of FIGS. 1 and 2. In the example of FIG. 7, the operations 700 are illustrated and described in connection with using the PWM signal to verify the SAFE signal. Alternatively, in other examples, the operations 700 may be modified to use the enable signal to verify the SAFE signal.

The example operations 700 begin at Block 705, at which the safe timer circuitry 610 of FIG. 6 determines if the safe state has changed in less than a threshold duration. (Block 705). In example operations, the safe timer circuitry 610 determines a duration since the safe signal has changed logical states. In such example operations, the safe timer circuitry 610 determines if the state of the safe signal needs to be verified based on a comparison of the determined duration to the threshold duration. If the safe timer circuitry 610 determines that the safe state has changed in less than the threshold duration (e.g., Block 705 returns a result of YES), control proceeds to return.

If the safe timer circuitry 610 determines that the safe state has not changed in less than the threshold duration (e.g., Block 705 returns a result of NO), the pulse generator circuitry 620 of FIG. 6 generates a test pulse. (Block 710). In example operations, the pulse generator circuitry 620 generates a test pulse having a test duration responsive to the safe timer circuitry 610 determining that the state the safe signal is to be verified. In some examples, the test duration of the test pulse is set based on the deglitch circuitry 175 of FIG. 1. In such examples, the test duration is less than a minimum duration that the deglitch circuitry 175 allows to control the transistor 135.

The logic device 640 of FIG. 6 combines the test pulse with the PWM pulse. (Block 715). In example operations, the logic device 640 logically combines the test pulse and the PWM signal from the PWM source circuitry 630 of FIG. 6. In such example operations, the logic device 640 supplies the combined PWM signal to the isolated gate driver circuitry 145, 200.

The current sense circuitry 180, 208 of FIGS. 1 and 2 determines if current is being injected into the inductor-capacitor circuit. (Block 720). In example operations, the current sense circuitry 180, 208 sets the state of the safe signal responsive to operations of the charge injection circuitry 160, 204, such as the example operations of Block 430 of FIG. 4.

If the current sense circuitry 180, 208 determines that current is being injected into the inductor capacitor circuit (e.g., Block 720 returns a result of YES), the current sense circuitry 180, 208 sets the SAFE signal to a logic zero. (Block 725). In example operations, the resistor 264 of FIG. 2 generates a reference voltage responsive to the charge injection circuitry 204 structuring the transistor 262 to conduct current. In such example operations, the comparator circuitry 266 of FIG. 2 generates a logic one responsive to detecting the reference voltage of the resistor 264. The level shifter circuitry 268 of FIG. 2 converts voltages of the comparator circuitry 266 to logic levels of the programmable circuitry 105. For example, in instances in which the supply voltage is twelve volts and the programmable circuitry 105 is structured for five-volt signals, the level shifter circuitry 268 converts the voltages of the comparator circuitry 266 for the programmable circuitry 105. The buffer circuitry 270 of FIG. 2 buffers signals from the level shifter circuitry 268 to increase signal strength. The inverter 272 of FIG. 2 generates the safe signal (SAFE) by inverting the logical state of the output of the buffer circuitry 270. In some examples, the current sense circuitry 180, 208 sets the safe signal to a logic zero responsive to the transistor 262 conducting current.

If the current sense circuitry 180, 208 determines that current is not being injected into the inductor capacitor circuit (e.g., Block 720 returns a result of NO), the current sense circuitry 180, 208 sets the SAFE signal to a logic one. (Block 730). In example operations, the resistor 264 sets the input of the comparator circuitry 266 to the common potential responsive to the charge injection circuitry 204 failing to structure the transistor 262 to conduct current. In such example operations, the level shifter circuitry 268 converts voltages of the comparator circuitry 266 to logic levels of the programmable circuitry 105. In some examples, the current sense circuitry 180, 208 sets the safe signal to a logic one responsive to the resistor 264 setting the input of the comparator circuitry 266 to the common potential.

The safe monitor circuitry 650 of FIG. 6 determines if the safe signal is opposite of the PWM signal. (Block 735). In example operations, the programmable circuitry 105 determines if the isolated gate driver circuitry 145, 200 is safely operating responsive to a comparison of the safe signal from the current sense circuitry 180, 208 to the combined PWM signal. In such example operations, the programmable circuitry 105 determines the isolated gate driver circuitry 145, 200 is safely operating responsive to the PWM signal having a logical state opposite of the logical state of the safe signal. In some examples, the output stage circuitry 130, 320, 350 of FIGS. 1, 3A, and 3B combines a plurality of safe signals from a plurality of instances of the isolated gate driver circuitry 145, 200. In such examples, the programmable circuitry 105 compares the system fault signal to one or more PWM signals to determine if all instances of the isolated gate driver circuitry 145, 200 are safely operating. In the example of FIG. 3A, the programmable circuitry 105 determines one or more of the driver circuitry 305, 310, 315 of FIG. 3A are not safely operating responsive to the system fault signal being a logic zero under the condition of all of the PWM signals being a logic zero. In such an example, the logic device 325 indicates that at least one safe signal from the driver circuitry 305, 310, 315 corresponds to current conduction. In the example of FIG. 3B, the resistor 355 of FIG. 3B allows any of the safe signals from the driver circuitry 335, 340, 345 to set the system fault signal.

If the safe monitor circuitry 650 determines the safe signal is not opposite of the PWM signal (e.g., Block 735 returns a result of NO), the PWM source circuitry 630 of FIG. 3 turns off driver circuitry. (Block 740). In example operations, the programmable circuitry 105 sets at least one of the PWM signal or the enable signal to a safe state responsive to a determination that the isolated gate driver circuitry 145, 200 is unintentionally conducting current.

The deglitch circuitry 175 of FIG. 1 filters the test pulse on a secondary side. (Block 745). In example operations, the deglitch circuitry 175 removes pulses having a duration less than a minimum duration to prevent the isolated gate driver circuitry 145, 200 from switching the transistor 135. In such example operations, the pulse generator circuitry 620 sets the test duration of the test pulse to be less than the minimum duration of the deglitch circuitry 175 to prevent the test pulse from modifying operations of the isolated gate driver circuitry 145, 200. Control proceeds to return.

Example methods are described with reference to the flowchart illustrated in FIG. 4. However, many other methods of implementing the isolated gate driver circuitry 145, 200 of FIGS. 1 and 2, the programmable circuitry 105, 600 of FIGS. 1 and 6 may also be used in this description. For example, the order of execution of the blocks may be changed, or some of the blocks described may be changed, eliminated, or combined. Similarly, additional operations may be included in the manufacturing process before, in between, or after the blocks shown in the illustrated examples.

FIG. 8 is a timing diagram 800 of example operations of the programmable circuitry 105, 600 of FIGS. 1 and 6 to deglitch a safety state of the isolated gate driver circuitry 145, 200 of FIGS. 1 and 2. In the example of FIG. 8, the timing diagram 800 illustrates an example safe signal 810 and an example gate control signal 820.

The safe signal 810 represents a signal from the current sense circuitry 180, 208 of FIGS. 1 and 2. The safe signal 810 represents whether the charge injection circuitry 160, 204 is supplying current to the transformer circuitry 165, 206. The current sense circuitry 180, 208 clears the safe signal 810 responsive to the charge injection circuitry 160, 204 being structured to supply current to the transformer circuitry 165, 206.

The gate control signal 820 represents a signal from the isolated gate driver circuitry 145, 200 that controls the transistor 135. In example operations, the transistor 135 supplies current to the motor 125 responsive to the gate control signal 820 being set. In such example operations, the transistor 135 prevents current flowing from the supply terminal to the motor 125 responsive to the gate control signal 820 being cleared.

At a first time 830, the logic circuitry 155, 202 structures the charge injection circuitry 160, 204 to supply current to the transformer circuitry 165, 206 responsive to a PWM signal (e.g., the PWM signal 510 of FIG. 5) and an enable signal (e.g., the enable signal 520 of FIG. 5) being set. At the first time 830, the current sense circuitry 180, 208 clears the safe signal 810 responsive to the charge injection circuitry 160 204 being structured to supply current to the transformer circuitry 165, 206.

Between the first time 830 and a second time 840, the pulse generator circuitry 620 of FIG. 6 generates a test pulse responsive to the safe timer circuitry 610 of FIG. 6 determining that the safe signal has not changed within a threshold duration (e.g., the operations of Block 705 of FIG. 7). The logic device 640 of FIG. 6 combines a reference PWM signal from the PWM source circuitry 630 of FIG. 6 and the test pulse to a PWM signal with the test pulse to the isolated gate driver circuitry 145, 200. At the second time 840, the logic circuitry 155, 202 structures the charge injection circuitry 160, 204 to prevent a supply of current to the transformer circuitry 165, 206. At the second time 840, the current sense circuitry 180, 208 sets the safe signal 530 responsive to the charge injection circuitry 160, 204 being structured to prevent the flow of current. However, if at the second time 840, the transistor 242 of FIG. 2 continues to conduct current, the programmable circuitry 105, 600 may detect a system fault responsive to the safe signal 810 remaining in a cleared state. Advantageously, the test pulse at the second time 840 allows the programmable circuitry 105, 600 to test the accuracy of the safe signal 810.

Between the second time 840 and a third time 850, the programmable circuitry 105, 600 continues to supply the test pulse to the isolated gate driver circuitry 145, 200. Between the second time 840 and the third time 850, the gate control signal 820 remains set responsive to the deglitch circuitry 175 of FIG. 1 filtering out the test pulse. In example operation, the deglitch circuitry 175 is structured to filter pulses having durations less than a maximum switching time. In such example operations, the test pulses do not cause the isolated gate driver circuitry 145, 200 to modify the state of the transistor 135 if the programmable circuitry 105, 600 sets the duration of the test pulse to be less than a minimum duration corresponding to a maximum switching frequency. Advantageously, the deglitch circuitry 175 allows the programmable circuitry 105, 600 to verify the accuracy of the safe signal 810 without impacting the transistor 135.

At a fourth time 860, the logic circuitry 155, 202 structures the charge injection circuitry 160, 204 to prevent a supply of current to the transformer circuitry 165, 206. At the fourth time 860, the current sense circuitry 180, 208 sets the safe signal 810 responsive to the charge injection circuitry 160, 204 being structured to not supply a current to the transformer circuitry 165, 206.

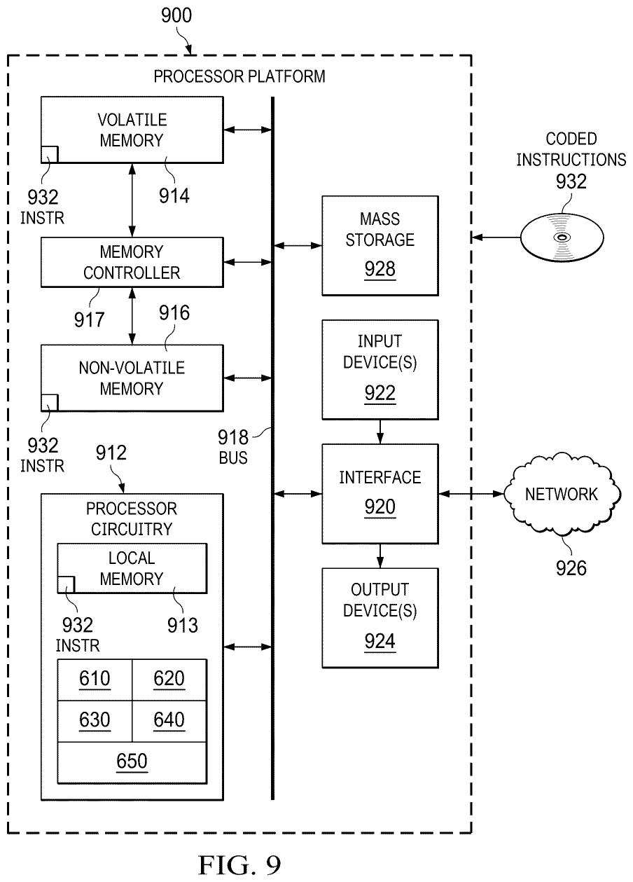

FIG. 9 is a block diagram of an example programmable circuitry platform 900 structured to one or a combination of execute or instantiate one or more of the example machine-readable instructions or the example operations of FIGS. 4 and 7 to implement the programmable circuitry 600 of FIG. 6. The programmable circuitry platform 900 can be, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, a DVD player, a CD player, a digital video recorder, a Blu-ray player, a gaming console, a personal video recorder, a set top box, a headset (e.g., an augmented reality (AR) headset, a virtual reality (VR) headset, etc.) or other wearable device, or any other type of computing or electronic device.

The programmable circuitry platform 900 of the illustrated example includes programmable circuitry 912. The programmable circuitry 912 of the illustrated example is hardware. For example, the programmable circuitry 912 can be implemented by one or more integrated circuits, logic circuits, FPGAs, microprocessors, CPUs, GPUs, DSPs, or microcontrollers from any desired family or manufacturer. The programmable circuitry 912 may be implemented by one or more semiconductor based (e.g., silicon based) devices. In this example, the programmable circuitry 912 implements the safe timer circuitry 610, the pulse generator circuitry 620, the PWM source circuitry 630, and the safe monitor circuitry 650.

The programmable circuitry 912 of the illustrated example includes a local memory 913 (e.g., a cache, registers, etc.). The programmable circuitry 912 of the illustrated example is in communication with main memory 914, 916, which includes a volatile memory 914 and a non-volatile memory 916, by a bus 918. The volatile memory 914 may be implemented by one or more Synchronous Dynamic Random Access Memory (SDRAM), Dynamic Random Access Memory (DRAM), RAMBUS® Dynamic Random Access Memory (RDRAM®), or any other type of RAM device. The non-volatile memory 916 may be implemented by one or a combination of flash memory or any other desired type of memory device. Access to the main memory 914, 916 of the illustrated example is controlled by a memory controller 917. In some examples, the memory controller 917 may be implemented by one or more integrated circuits, logic circuits, microcontrollers from any desired family or manufacturer, or any other type of circuitry to manage the flow of data going to and from the main memory 914, 916.

The programmable circuitry platform 900 of the illustrated example also includes interface circuitry 920. The interface circuitry 920 may be implemented by hardware in according to any type of interface standard, such as an Ethernet interface, a universal serial bus (USB) interface, a Bluetooth® interface, a near field communication (NFC) interface, a Peripheral Component Interconnect (PCI) interface, or a Peripheral Component Interconnect Express (PCIe) interface.

In the illustrated example, one or more input devices 922 are connected to the interface circuitry 920. The input device(s) 922 permit(s) a user (e.g., a human user, a machine user, etc.) to enter one of or a combination of data or commands into the programmable circuitry 912. The input device(s) 922 can be implemented by, for example, one of or a combination of an audio sensor, a microphone, a camera (still or video), a keyboard, a button, a mouse, a touchscreen, a trackpad, a trackball, an isopoint device, or a voice recognition system.

One or more output devices 924 are also connected to the interface circuitry 920 of the illustrated example. The output device(s) 924 can be implemented, for example, by one of or a combination of display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, or speaker. The interface circuitry 920 of the illustrated example, thus, includes one of or a combination of a graphics driver card, a graphics driver chip, or graphics processor circuitry such as a GPU.

The interface circuitry 920 of the illustrated example also includes a communication device such as one of or a combination of a transmitter, a receiver, a transceiver, a modem, a residential gateway, a wireless access point, or a network interface to facilitate exchange of data with external machines (e.g., computing devices of any kind) by a network 926. The communication can be by, for example, an Ethernet connection, a digital subscriber line (DSL) connection, a telephone line connection, a coaxial cable system, a satellite system, a beyond-line-of-sight wireless system, a line-of-sight wireless system, a cellular telephone system, an optical connection, etc.

The programmable circuitry platform 900 of the illustrated example also includes one or more mass storage discs or devices 928 to store one or more of firmware, software, or data. Examples of such mass storage discs or devices 928 include one or more magnetic storage devices (e.g., floppy disk, drives, HDDs, etc.), optical storage devices (e.g., Blu-ray disks, CDs, DVDs, etc.), RAID systems, or solid-state storage discs or devices such as flash memory devices and SSDs.

The machine-readable instructions 932, which may be implemented by the machine-readable instructions of FIGS. 4 and 7, may be stored in one of or a combination of the mass storage device 928, in the volatile memory 914, in the non-volatile memory 916, or on at least one non-transitory computer readable storage medium such as a CD or DVD which may be removable.

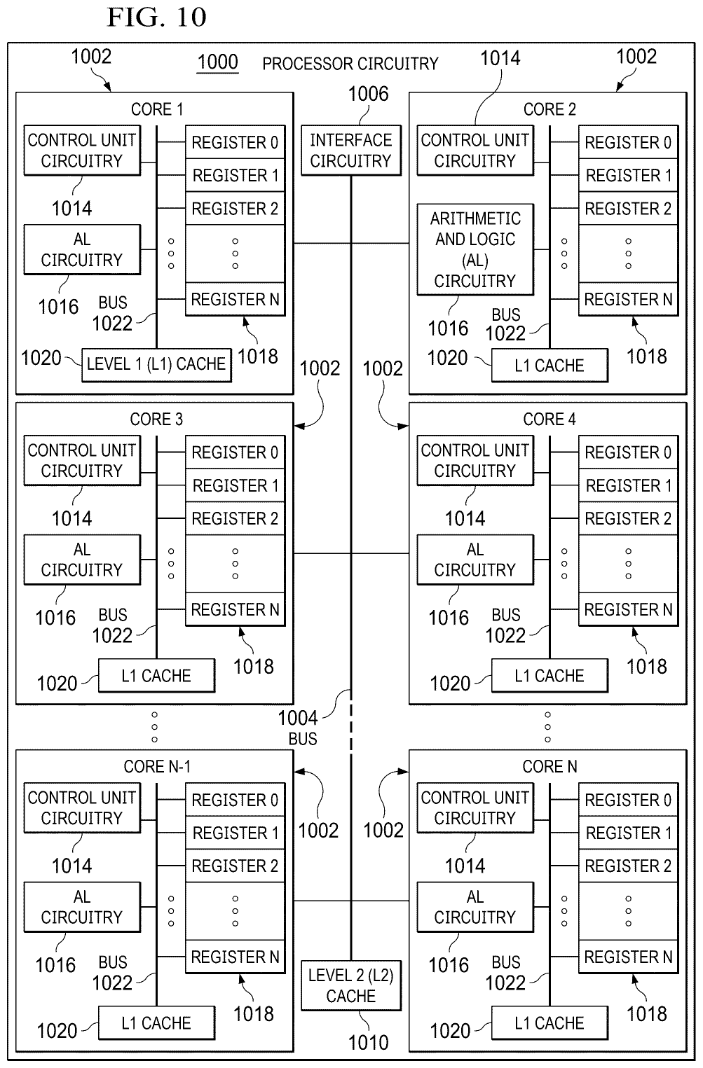

FIG. 10 is a block diagram of an example implementation of the programmable circuitry 912 of FIG. 9. In this example, the programmable circuitry 912 of FIG. 9 is implemented by a microprocessor 1000. For example, the microprocessor 1000 may be a general-purpose microprocessor (e.g., general-purpose microprocessor circuitry). The microprocessor 1000 executes some or all of the machine-readable instructions of the flowcharts of FIGS. 4 and 7 to effectively instantiate the circuitry of FIG. 6 as logic circuits to perform operations corresponding to those machine-readable instructions. In some such examples, the circuitry of FIG. 6 is instantiated by the hardware circuits of the microprocessor 1000 in combination with the machine-readable instructions. For example, the microprocessor 1000 may be implemented by multi-core hardware circuitry such as a CPU, a DSP, a GPU, an XPU, etc. Although it may include any number of example cores 1002 (e.g., 1 core), the microprocessor 1000 of this example is a multi-core semiconductor device including N cores. The cores 1002 of the microprocessor 1000 may operate independently or may cooperate to execute machine-readable instructions. For example, machine code corresponding to a firmware program, an embedded software program, or a software program may be executed by one of the cores 1002 or may be executed by multiple ones of the cores 1002 at the same or different times. In some examples, the machine code corresponding to the firmware program, the embedded software program, or the software program is split into threads and executed in parallel by two or more of the cores 1002. The software program may correspond to a portion or all of the machine-readable instructions or operations represented by the flowcharts of FIGS. 4 and 7.

The cores 1002 may communicate by a first example bus 1004. In some examples, the first bus 1004 may be implemented by a communication bus to effectuate communication associated with one(s) of the cores 1002. For example, the first bus 1004 may be implemented by at least one of an Inter-Integrated Circuit (I2C) bus, a Serial Peripheral Interface (SPI) bus, a PCI bus, or a PCIe bus. Also or alternatively, the first bus 1004 may be implemented by any other type of computing or electrical bus. The cores 1002 may obtain data, instructions, and signals from one or more external devices by example interface circuitry 1006. The cores 1002 may output data, instructions, and signals to the one or more external devices by the interface circuitry 1006. Although the cores 1002 of this example include example local memory 1020 (e.g., Level 1 (L1) cache that may be split into an L1 data cache and an L1 instruction cache), the microprocessor 1000 also includes example shared memory 1010 that may be shared by the cores (e.g., Level 2 (L2 cache)) for high-speed access to data and instructions. Data and instructions may be transferred (e.g., shared) by one of or a combination of writing to or reading from the shared memory 1010. The local memory 1020 of each of the cores 1002 and the shared memory 1010 may be part of a hierarchy of storage devices including multiple levels of cache memory and the main memory (e.g., the main memory 914, 916 of FIG. 9). In some cases, higher levels of memory in the hierarchy exhibit lower access time and have smaller storage capacity than lower levels of memory. Changes in the various levels of the cache hierarchy are managed (e.g., coordinated) by a cache coherency policy.

Each core 1002 may be referred to as a CPU, DSP, GPU, etc., or any other type of hardware circuitry. Each core 1002 includes control unit circuitry 1014, arithmetic and logic (AL) circuitry (sometimes referred to as an ALU) 1016, a plurality of registers 1018, the local memory 1020, and a second example bus 1022. Other structures may be present. For example, each core 1002 may include vector unit circuitry, single instruction multiple data (SIMD) unit circuitry, load/store unit (LSU) circuitry, branch/jump unit circuitry, floating-point unit (FPU) circuitry, etc. The control unit circuitry 1014 includes semiconductor-based circuits structured to control (e.g., coordinate) data movement within the corresponding core 1002. The AL circuitry 1016 includes semiconductor-based circuits structured to perform one or more mathematic or logic operations on the data within the corresponding core 1002. The AL circuitry 1016 of some examples performs integer-based operations. In other examples, the AL circuitry 1016 also performs floating-point operations. In yet other examples, the AL circuitry 1016 may include first AL circuitry that performs integer-based operations and second AL circuitry that performs floating-point operations. In some examples, the AL circuitry 1016 may be referred to as an Arithmetic Logic Unit (ALU).

The registers 1018 are semiconductor-based structures to store data and instructions such as results of one or more of the operations performed by the AL circuitry 1016 of the corresponding core 1002. For example, the registers 1018 may include vector register(s), SIMD register(s), general-purpose register(s), flag register(s), segment register(s), machine-specific register(s), instruction pointer register(s), control register(s), debug register(s), memory management register(s), machine check register(s), etc. The registers 1018 may be arranged in a bank as shown in FIG. 10. Alternatively, the registers 1018 may be organized in any other arrangement, format, or structure, such as by being distributed throughout the core 1002 to shorten access time. The second bus 1022 may be implemented by at least one of an I2C bus, a SPI bus, a PCI bus, or a PCIe bus.

Each core 1002 or, more generally, the microprocessor 1000 may include additional or alternate structures to those shown and described above. For example, one or more clock circuits, one or more power supplies, one or more power gates, one or more cache home agents (CHAs), one or more converged/common mesh stops (CMSs), one or more shifters (e.g., barrel shifter(s)) or other circuitry may be present. The microprocessor 1000 is a semiconductor device fabricated to include many transistors interconnected to implement the structures described above in one or more integrated circuits (ICs) contained in one or more packages.

The microprocessor 1000 may include or cooperate with one or more accelerators (e.g., acceleration circuitry, hardware accelerators, etc.). In some examples, accelerators are implemented by logic circuitry to perform certain tasks more quickly and efficiently than can be done by a general-purpose processor. Examples of accelerators include ASICs and FPGAs such as those described herein. A GPU, DSP, or other programmable device can also be an accelerator. Accelerators may be on-board the microprocessor 1000, in the same chip package as the microprocessor 1000, or in one or more separate packages from the microprocessor 1000.

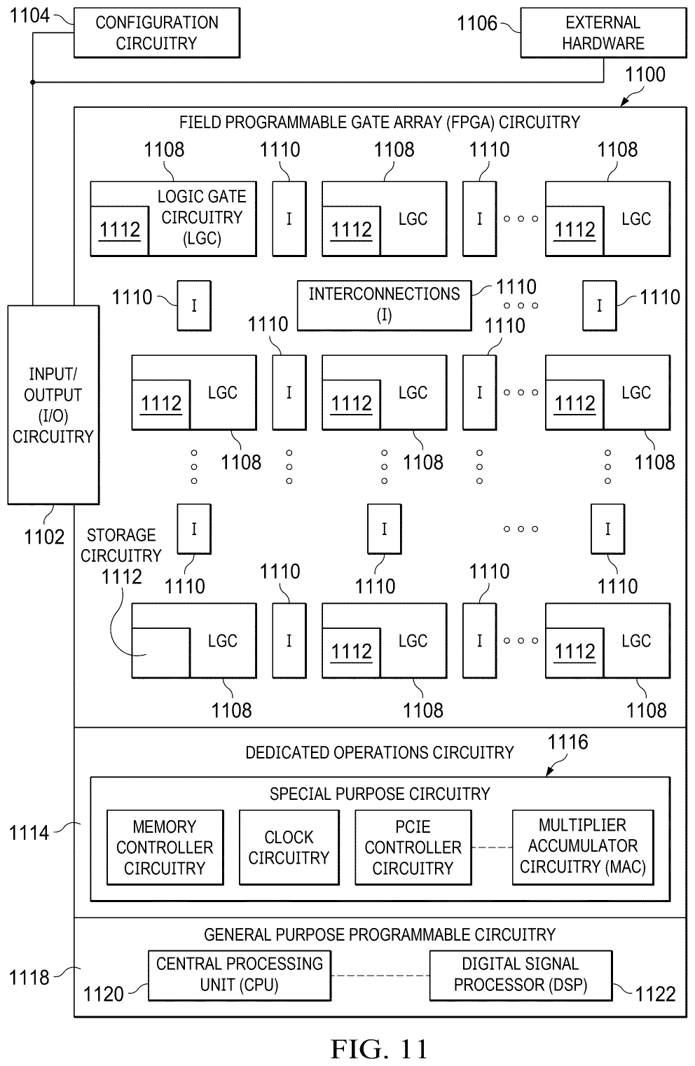

FIG. 11 is a block diagram of another example implementation of the programmable circuitry 912 of FIG. 9. In this example, the programmable circuitry 912 is implemented by FPGA circuitry 1100. For example, the FPGA circuitry 1100 may be implemented by an FPGA. The FPGA circuitry 1100 can be used, for example, to perform operations that could otherwise be performed by the example microprocessor 1000 of FIG. 10 executing corresponding machine-readable instructions. However, once configured, the FPGA circuitry 1100 instantiates the operations and functions corresponding to the machine-readable instructions in hardware and, thus, can often execute the operations/functions faster than they could be performed by a general-purpose microprocessor executing the corresponding software.

More specifically, in contrast to the microprocessor 1000 of FIG. 10 described above (which is a general purpose device that may be programmed to execute some or all of the machine-readable instructions represented by the flowchart(s) of FIGS. 4 and 7 but whose interconnections and logic circuitry are fixed once fabricated), the FPGA circuitry 1100 of the example of FIG. 11 includes interconnections and logic circuitry that may be one of or a combination of configured, structured, programmed, and interconnected in different ways after fabrication to instantiate, for example, some or all of the operations/functions corresponding to the machine-readable instructions represented by the flowchart(s) of FIGS. 4 and 7. In particular, the FPGA circuitry 1100 may be thought of as an array of logic gates, interconnections, and switches. The switches can be programmed to change how the logic gates are interconnected by the interconnections, effectively forming one or more dedicated logic circuits (unless and until the FPGA circuitry 1100 is reprogrammed). The configured logic circuits enable the logic gates to cooperate in different ways to perform different operations on data received by input circuitry. Those operations may correspond to some or all of the instructions (e.g., the software and/or firmware) represented by the flowchart(s) of FIGS. 4 and 7. As such, the FPGA circuitry 1100 may be at least one of configured or structured to effectively instantiate some or all of the operations/functions corresponding to the machine-readable instructions of the flowchart(s) of FIGS. 4 and 7 as dedicated logic circuits to perform the operations/functions corresponding to those software instructions in a dedicated manner analogous to an ASIC. Therefore, the FPGA circuitry 1100 may perform the operations/functions corresponding to the some or all of the machine-readable instructions of FIGS. 4 and 7 faster than the general-purpose microprocessor can execute the same.

In the example of FIG. 11, the FPGA circuitry 1100 is at least one of configured or structured in response to being programmed (or reprogrammed one or more times) based on a binary file. In some examples, the binary file may be one of or both of compiled or generated based on instructions in a hardware description language (HDL) such as Lucid, Very High-Speed Integrated Circuits (VHSIC) Hardware Description Language (VHDL), or Verilog. For example, a user (e.g., a human user, a machine user, etc.) may write code or a program corresponding to one or more operations/functions in an HDL; the code/program may be translated into a low-level language as needed; and the code/program (e.g., the code/program in the low-level language) may be converted (e.g., by a compiler, a software application, etc.) into the binary file. In some examples, the FPGA circuitry 1100 of FIG. 11 may at least one of access or load the binary file to cause the FPGA circuitry 1100 of FIG. 11 to be at least one of configured or structured to perform the one or more operations/functions. For example, the binary file may be implemented by one of or a combination of a bit stream (e.g., one or more computer-readable bits, one or more machine-readable bits, etc.), data (e.g., computer-readable data, machine-readable data, etc.), or machine-readable instructions accessible to the FPGA circuitry 1100 of FIG. 11 to at least one of configure or structure the FPGA circuitry 1100 of FIG. 11, or portion(s) thereof.

In some examples, the binary file is at least one of compiled, generated, transformed, or otherwise output from a uniform software platform utilized to program FPGAs. For example, the uniform software platform may translate first instructions (e.g., code or a program) that correspond to one or more operations/functions in a high-level language (e.g., C, C++, Python, etc.) into second instructions that correspond to the one or more operations/functions in an HDL. In some such examples, the binary file is at least one of compiled, generated, or otherwise output from the uniform software platform based on the second instructions. In some examples, the FPGA circuitry 1100 of FIG. 11 may at least one of access or load the binary file to cause the FPGA circuitry 1100 of FIG. 11 to be at least one of configured or structured to perform the one or more operations/functions. For example, the binary file may be implemented by one of or a combination of a bit stream (e.g., one or more computer-readable bits, one or more machine-readable bits, etc.), data (e.g., computer-readable data, machine-readable data, etc.), or machine-readable instructions accessible to the FPGA circuitry 1100 of FIG. 11 to at least one of configure or structure the FPGA circuitry 1100 of FIG. 11, or portion(s) thereof.

The FPGA circuitry 1100 of FIG. 11, includes example input/output (I/O) circuitry 1102 to at least one of obtain or output data to/from at least one of example configuration circuitry 1104 or external hardware 1106. For example, the configuration circuitry 1104 may be implemented by interface circuitry that may obtain a binary file, which may be implemented by one or more of a bit stream, data, or machine-readable instructions, to configure the FPGA circuitry 1100, or portion(s) thereof. In some such examples, the configuration circuitry 1104 may obtain the binary file from one of or a combination of a user, a machine (e.g., hardware circuitry (e.g., programmable or dedicated circuitry) that may implement an Artificial Intelligence/Machine Learning (AI/ML) model to generate the binary file, etc.), or any combination(s) thereof). In some examples, the external hardware 1106 may be implemented by external hardware circuitry. For example, the external hardware 1106 may be implemented by the microprocessor 1000 of FIG. 10.

The FPGA circuitry 1100 also includes an array of example logic gate circuitry 1108, a plurality of example configurable interconnections 1110, and example storage circuitry 1112. The logic gate circuitry 1108 and the configurable interconnections 1110 are configurable to instantiate one or more operations/functions that may correspond to at least some of the machine-readable instructions of FIGS. 4 and 7 and/or other desired operations. The logic gate circuitry 1108 shown in FIG. 11 is fabricated in blocks or groups. Each block includes semiconductor-based electrical structures that may be configured into logic circuits. In some examples, the electrical structures include logic gates (e.g., And gates, Or gates, Nor gates, etc.) that provide basic building blocks for logic circuits. Electrically controllable switches (e.g., transistors) are present within each of the logic gate circuitry 1108 to enable configuration of one of or a combination of the electrical structures or the logic gates to form circuits to perform desired operations/functions. The logic gate circuitry 1108 may include other electrical structures such as look-up tables (LUTs), registers (e.g., flip-flops or latches), multiplexers, etc.

The configurable interconnections 1110 of the illustrated example are conductive pathways, traces, vias, or the like that may include electrically controllable switches (e.g., transistors) whose state can be changed by programming (e.g., using an HDL instruction language) to activate or deactivate one or more connections between one or more of the logic gate circuitry 1108 to program desired logic circuits.

The storage circuitry 1112 of the illustrated example is structured to store result(s) of the one or more of the operations performed by corresponding logic gates. The storage circuitry 1112 may be implemented by registers or the like. In the illustrated example, the storage circuitry 1112 is distributed amongst the logic gate circuitry 1108 to facilitate access and increase execution speed.

The example FPGA circuitry 1100 of FIG. 11 also includes example dedicated operations circuitry 1114. In this example, the dedicated operations circuitry 1114 includes special purpose circuitry 1116 that may be invoked to implement commonly used functions to avoid the need to program those functions in the field. Examples of such special purpose circuitry 1116 include memory (e.g., DRAM) controller circuitry, PCIe controller circuitry, clock circuitry, transceiver circuitry, memory, and multiplier-accumulator circuitry. Other types of special purpose circuitry may be present. In some examples, the FPGA circuitry 1100 may also include example general purpose programmable circuitry 1118 such as an example CPU 1120 or an example DSP 1122. Other general purpose programmable circuitry 1118 may also or alternatively be present such as a GPU, an XPU, etc., that can be programmed to perform other operations.

Although FIGS. 10 and 11 illustrate two example implementations of the programmable circuitry 912 of FIG. 9, many other approaches are contemplated. For example, FPGA circuitry may include an on-board CPU, such as one or more of the example CPU 1120 of FIG. 10. Therefore, the programmable circuitry 912 of FIG. 9 may also be implemented by combining at least the example microprocessor 1000 of FIG. 10 and the example FPGA circuitry 1100 of FIG. 11. In some such hybrid examples, one or more cores 1002 of FIG. 10 may execute a first portion of the machine-readable instructions represented by the flowchart(s) of FIGS. 4 and 7 to perform first operation(s)/function(s), the FPGA circuitry 1100 of FIG. 11 may be at least one of configured or structured to perform second operation(s)/function(s) corresponding to a second portion of the machine-readable instructions represented by the flowcharts of FIGS. 4 and 7, and/or an ASIC may be at least one of configured or structured to perform third operation(s)/function(s) corresponding to a third portion of the machine-readable instructions represented by the flowcharts of FIGS. 4 and 7.

Some or all of the circuitry of FIG. 6 may, thus, be instantiated at the same or different times. For example, same and/or different portion(s) of the microprocessor 1000 of FIG. 10 may be programmed to execute portion(s) of machine-readable instructions at the same and/or different times. In some examples, same and/or different portion(s) of the FPGA circuitry 1100 of FIG. 11 may be at least one of configured or structured to perform operations/functions corresponding to portion(s) of machine-readable instructions at the same and/or different times.

In some examples, some or all of the circuitry of FIG. 6 may be instantiated, for example, in one or more threads executing concurrently and/or in series. For example, the microprocessor 1000 of FIG. 10 may execute machine-readable instructions in one or more threads executing concurrently and/or in series. In some examples, the FPGA circuitry 1100 of FIG. 11 may be at least one of configured or structured to carry out operations/functions concurrently and/or in series. Moreover, in some examples, some or all of the circuitry of FIG. 6 may be implemented within one or more virtual machines or containers executing on the microprocessor 1000 of FIG. 10.

In some examples, the programmable circuitry 912 of FIG. 9 may be in one or more packages. For example, at least one of the microprocessor 1000 of FIG. 10 or the FPGA circuitry 1100 of FIG. 11 may be in one or more packages. In some examples, an XPU may be implemented by the programmable circuitry 912 of FIG. 9, which may be in one or more packages. For example, the XPU may include a CPU (e.g., the microprocessor 1000 of FIG. 10, the CPU 1120 of FIG. 11, etc.) in one package, a DSP (e.g., the DSP 1122 of FIG. 11) in another package, a GPU in yet another package, and an FPGA (e.g., the FPGA circuitry 1100 of FIG. 11) in still yet another package.

While an example manner of implementing the programmable circuitry 105 of FIG. 1 is illustrated in FIG. 6, one or more of the elements, processes, or devices illustrated in FIG. 6 may be combined, divided, re-arranged, omitted, eliminated, or implemented in any other way. Further, the safe timer circuitry 610, the pulse generator circuitry 620, the PWM source circuitry 630, and the safe monitor circuitry 650 or, more generally, the example programmable circuitry 600 of FIG. 6, may be implemented by hardware alone or by hardware in combination with software and firmware. Thus, for example, any of the safe timer circuitry 610, the pulse generator circuitry 620, the PWM source circuitry 630, and the safe monitor circuitry 650, or, more generally, the example programmable circuitry 600, could be implemented by programmable circuitry in combination with one or more machine-readable instructions (e.g., firmware or software), processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), or field programmable logic device(s) (FPLD(s)) such as FPGAs. Further still, the example programmable circuitry 600 of FIG. 6 may include one or more elements, processes, or devices in addition to, or instead of, those illustrated in FIG. 6, or may include more than one of any or all of the illustrated elements, processes and devices.

Flowchart(s) representative of example machine-readable instructions, which may be executed by programmable circuitry to at least one of implement or instantiate the programmable circuitry 600 of FIG. 6 or representative of example operations which may be performed by programmable circuitry to at least one of implement or instantiate the programmable circuitry 600 of FIG. 6, are shown in FIGS. 4 and 7. The machine-readable instructions may be one or more executable programs or portion(s) of one or more executable programs for execution by programmable circuitry such as the programmable circuitry 912 shown in the example processor platform 900 described below in connection with FIG. 9 and may be one or more function(s) or portion(s) of functions to be performed by the example programmable circuitry (e.g., an FPGA) described below in connection with FIG. 10 or 11. In some examples, the machine-readable instructions cause an operation, a task, etc., to be carried out or performed in an automated manner in the real-world. As used herein, “automated” means without human involvement.

The program may be embodied in instructions (e.g., software and/or firmware) stored on one or more non-transitory computer readable and/or machine-readable storage medium such as one of or a combination of cache memory, a magnetic-storage device or disk (e.g., a floppy disk, a Hard Disk Drive (HDD), etc.), an optical-storage device or disk (e.g., a Blu-ray disk, a Compact Disk (CD), a Digital Versatile Disk (DVD), etc.), a Redundant Array of Independent Disks (RAID), a register, ROM, a solid-state drive (SSD), SSD memory, non-volatile memory (e.g., electrically erasable programmable read-only memory (EEPROM), flash memory, etc.), volatile memory (e.g., Random Access Memory (RAM) of any type, etc.), or any other storage device or storage disk. The instructions of the non-transitory computer readable and/or machine-readable medium may program or be executed by programmable circuitry located in one or more hardware devices, but the entire program or parts thereof could alternatively be executed or instantiated by one or more hardware devices other than the programmable circuitry or embodied in dedicated hardware. The machine-readable instructions may be distributed across multiple hardware devices or executed by two or more hardware devices (e.g., a server and a client hardware device). For example, the client hardware device may be implemented by an endpoint client hardware device (e.g., a hardware device associated with a human and/or machine user) or an intermediate client hardware device gateway (e.g., a radio access network (RAN)) that may facilitate communication between a server and an endpoint client hardware device. Similarly, the non-transitory computer readable storage medium may include one or more mediums. Further, although the example program is described with reference to the flowchart(s) illustrated in FIGS. 4 and 7, many other methods of implementing the example programmable circuitry 600 of FIG. 6 may alternatively be used. For example, the order of execution of the blocks of the flowchart(s) may be changed, or some of the blocks described may be changed, eliminated, or combined. Also or alternatively, any or all of the blocks of the flow chart may be implemented by one or more hardware circuits (e.g., processor circuitry, discrete, integrated analog and/or digital circuitry, an FPGA, an ASIC, a comparator, an operational-amplifier (op-amp), a logic circuit, etc.) structured to perform the corresponding operation without executing software or firmware. The programmable circuitry may be distributed in different network locations or local to one or more hardware devices (e.g., a single-core processor (e.g., a single core CPU), a multi-core processor (e.g., a multi-core CPU, an XPU, etc.)). For example, the programmable circuitry may be one of or a combination of a CPU or an FPGA located in the same package (e.g., the same integrated circuit (IC) package or in two or more separate housings), one or more processors in a single machine, multiple processors distributed across multiple servers of a server rack, multiple processors distributed across one or more server racks, etc., or any combination(s) thereof.

The machine-readable instructions described herein may be stored in one or more of a compressed format, an encrypted format, a fragmented format, a compiled format, an executable format, a packaged format, etc. Machine readable instructions as described herein may be stored as data (e.g., computer-readable data, machine-readable data, one or more bits (e.g., one or more computer-readable bits, one or more machine-readable bits, etc.), a bitstream (e.g., a computer-readable bitstream, a machine-readable bitstream, etc.), etc.) or a data structure (e.g., as portion(s) of instructions, code, representations of code, etc.) that may be utilized to create, manufacture, or produce machine executable instructions. For example, the machine-readable instructions may be fragmented and stored on one or more storage devices, disks or computing devices (e.g., servers) located at the same or different locations of a network or collection of networks (e.g., in the cloud, in edge devices, etc.). The machine-readable instructions may require one or more of installation, modification, adaptation, updating, combining, supplementing, configuring, decryption, decompression, unpacking, distribution, reassignment, compilation, etc., in order to render them directly readable, interpretable, or executable by a computing device or other machine. For example, the machine-readable instructions may be stored in multiple parts, which are individually compressed, encrypted, or stored on separate computing devices. The parts when decrypted, decompressed, or combined form a set of one or more computer-executable or machine executable instructions that implement one or more functions or operations that may together form a program such as that described herein.

In another example, the machine-readable instructions may be stored in a state in which they may be read by programmable circuitry, but require addition of a library (e.g., a dynamic link library (DLL)), a software development kit (SDK), an application programming interface (API), etc., in order to execute the machine-readable instructions on a particular computing device or other device. In another example, the machine-readable instructions may need to be configured (e.g., settings stored, data input, network addresses recorded, etc.) before the machine-readable instructions or the corresponding program(s) can be executed in whole or in part. Thus, machine-readable, computer readable or machine-readable media, as used herein, may include one or a combination of instructions and program(s) regardless of the particular format or state of the machine-readable instructions or program(s).

The machine-readable instructions described herein can be represented by any past, present, or future instruction language, scripting language, programming language, etc. For example, the machine-readable instructions may be represented using any of the following languages: C, C++, Java, C #, Perl, Python, JavaScript, HyperText Markup Language (HTML), Structured Query Language (SQL), Swift, etc.

As mentioned above, the example operations of FIGS. 4 and 7 may be implemented using executable instructions (e.g., computer readable and/or machine-readable instructions) stored on one or more non-transitory computer readable or machine-readable media. As used herein, the terms non-transitory computer readable medium, non-transitory computer readable storage medium, non-transitory machine-readable medium, and non-transitory machine-readable storage medium are expressly defined to include any type of computer readable storage device or storage disk and to exclude propagating signals and to exclude transmission media. Examples of such non-transitory computer readable medium, non-transitory computer readable storage medium, non-transitory machine-readable medium, or non-transitory machine-readable storage medium include one or more optical storage devices, magnetic storage devices, an HDD, a flash memory, a read-only memory (ROM), a CD, a DVD, a cache, a RAM of any type, a register, or any other storage device or storage disk in which information is stored for any duration (e.g., for extended time periods, permanently, for brief instances, for temporarily buffering, for caching of the information). As used herein, the terms “non-transitory computer readable storage device” and “non-transitory machine-readable storage device” are defined to include any physical (mechanical, magnetic, electromechanical, or electrical) hardware to retain information for a time period, but to exclude propagating signals and to exclude transmission media. Examples of non-transitory computer readable storage devices or non-transitory machine-readable storage devices include one or a combination of random-access memory of any type, read only memory of any type, solid state memory, flash memory, optical discs, magnetic disks, disk drives, or redundant array of independent disks (RAID) systems. As used herein, the term “device” refers to physical structure such as one of or a combination of mechanical, electromechanical, or electrical equipment, hardware, or circuitry that may or may not be configured by computer readable instructions, machine-readable instructions, etc., or manufactured to execute computer-readable instructions, machine-readable instructions, etc.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and things, the phrase “at least one of A and B” refers to implementations including any of (1) at least one A, (2) at least one B, or (3) at least one A and at least one B. Similarly, as used herein in the context of describing structures, components, items, objects and things, the phrase “at least one of A or B” refers to implementations including any of (1) at least one A, (2) at least one B, or (3) at least one A and at least one B. As used herein in the context of describing the performance or execution of processes, instructions, actions, activities, etc., the phrase “at least one of A and B” refers to implementations including any of (1) at least one A, (2) at least one B, or (3) at least one A and at least one B. Similarly, as used herein in the context of describing the performance or execution of processes, instructions, actions, activities, etc., the phrase “at least one of A or B” refers to implementations including any of (1) at least one A, (2) at least one B, or (3) at least one A and at least one B.

As used herein, singular references (e.g., “a,” “an,” “first,” “second,” etc.) do not exclude a plurality. The term “a” or “an” object, as used herein, refers to one or more of that objects. The terms “a” (or “an”), “one or more,” and “at least one” are used interchangeably herein. Furthermore, although individually listed, a plurality of means, elements, or actions may be implemented by, e.g., the same entity or object. Also, although individual features may be included in different examples or claims, these may possibly be combined, and the inclusion in different examples or claims does not imply that a combination of features is at least one of not feasible or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by at least one of the connection reference or relative movement between those elements unless otherwise indicated. As such, connection references do not necessarily infer that two elements are directly connected or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, or ordering in any way, but are merely used as at least one of labels or arbitrary names to distinguish elements for ease of understanding the described examples. In some examples, the descriptor “first” may be used to refer to an element in the detailed description, while the same element may be referred to in a claim with a different descriptor such as “second” or “third. ” In such instances, such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to at least one of manufacturing tolerances or other real-world imperfections. For example, “approximately” and “about” may indicate such dimensions may be within a tolerance range of +/−10% unless otherwise specified herein.

As used herein, the phrase “in communication,” including variations thereof, encompasses one of or a combination of direct communication or indirect communication through one or more intermediary components, and does not require direct physical (e.g., wired) communication or constant communication, but rather also includes selective communication at least one of periodic intervals, scheduled intervals, aperiodic intervals, or one-time events.

As used herein, “programmable circuitry” is defined to include at least one of (i) one or more special purpose electrical circuits (e.g., an application specific circuit (ASIC)) structured to perform specific operation(s) and including one or more semiconductor-based logic devices (e.g., electrical hardware implemented by one or more transistors), or (ii) one or more general purpose semiconductor-based electrical circuits programmable with instructions to perform one or more specific functions(s) or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations or functions, Field Programmable Gate Arrays (FPGAs) that may be programmed with second instructions to at least one of configure or structure the FPGAs to instantiate one or more operations or functions corresponding to the first instructions, Graphics Processor Units (GPUs) that may execute first instructions to perform one or more operations or functions, Digital Signal Processors (DSPs) that may execute first instructions to perform one or more operations or functions, XPUs, Network Processing Units (NPUs) one or more microcontrollers that may execute first instructions to perform one or more operations or functions or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., at least one of programmed or hardwired) at a time of manufacturing by a manufacturer to at least one of perform the function or be configurable (or re-configurable) by a user after manufacturing to perform the function /or other additional or alternative functions. The configuring may be through at least one of firmware or software programming of the device, through at least one of a construction or layout of hardware components and interconnections of the device, or a combination thereof.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

In the description and claims, described “circuitry” may include one or more circuits. A circuit or device that is described herein as including certain components may instead be adapted to be coupled to those components to form the described circuitry or device. For example, a structure described as including one or more semiconductor elements (such as transistors), one or more passive elements (such as one of or a combination of resistors, capacitors, or inductors), or one or more sources (such as voltage and/or current sources) may instead include only the semiconductor elements within a single physical device (e.g., at least one of a semiconductor die or integrated circuit (IC) package) and may be adapted to be coupled to at least some of the passive elements or the sources to form the described structure either at a time of manufacture or after a time of manufacture, for example, by at least one of an end-user or a third-party.

Circuits described herein are reconfigurable to include the replaced components to provide functionality at least partially similar to functionality available prior to the component replacement. Components shown as resistors, unless otherwise stated, are generally representative of any one or more elements coupled in at least one of series or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor. While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and some features illustrated as being internal to the integrated circuit may be incorporated outside of the integrated. As used herein, the term “integrated circuit” means one or more circuits that are at least one of: (i) incorporated in/over a semiconductor substrate; (ii) incorporated in a single semiconductor package; (iii) incorporated into the same module; or (iv) incorporated in/on the same printed circuit board.

Uses of the phrase “ground” in the foregoing description include at least one of a chassis ground, an Earth ground, a floating ground, a virtual ground, a digital ground, a common ground, or any other form of ground connection applicable to, or suitable for, the teachings of this description. Unless otherwise stated, “about,” “approximately,” or “substantially” preceding a value means +/−10 percent of the stated value, or, if the value is zero, a reasonable range of values around zero.

Modifications are possible in the described embodiments, and other embodiments are possible, within the scope of the claims.

What is claimed is:

1. An apparatus comprising:
charge injection circuitry having a first terminal, a second terminal, and a control terminal;
first inductor-capacitor (LC) circuitry having a first terminal and a second terminal, the first terminal of the first LC circuitry coupled to the first terminal of the charge injection circuitry, the second terminal of the first LC circuitry coupled to the second terminal of the charge injection circuitry;
second LC circuitry magnetically coupled to the first LC circuitry; and
current sense circuitry having an input terminal coupled to the control terminal of the charge injection circuitry.

2. The apparatus of claim 1, wherein the charge injection circuitry includes:
current source circuitry having a first terminal and a control terminal;
a first transistor having a first terminal, a second terminal, and a control terminal; and
a second transistor having a first terminal, a second terminal, and a control terminal, the first terminal of the second transistor is coupled to the first terminal of the current source circuitry and the first terminal of the first transistor, the second terminal of the second transistor is coupled to the first terminal of the first LC circuitry and the control terminal of the first transistor, the control terminal of the second transistor is coupled to the second terminal of the first LC circuitry and the second terminal of the first transistor.

3. The apparatus of claim 2, wherein the current source circuitry is a third transistor having a first terminal and a control terminal, the first terminal of the third transistor is coupled to the first terminal of the first transistor and the first terminal of the second transistor, the control terminal of the third transistor is coupled to the input terminal of the current sense circuitry.

4. The apparatus of claim 1, wherein the first LC circuitry including:
an inductor having a first terminal and a second terminal; and
a capacitor having a first terminal and a second terminal, the first terminal of the capacitor is coupled to the first terminal of the charge injection circuitry and the first terminal of the inductor, the second terminal of the capacitor is coupled to the second terminal of the charge injection circuitry and the second terminal of the inductor.

5. The apparatus of claim 1, wherein the current sense circuitry including:
a transistor having a first terminal and a control terminal, the control terminal of the transistor is coupled to the control terminal of the charge injection circuitry;
comparator circuitry having an input terminal and an output terminal, the input terminal of the comparator circuitry is coupled to the first terminal of the transistor; and
an inverter having an input terminal coupled to the output terminal of the comparator circuitry.

6. The apparatus of claim 5, wherein the current sense circuitry further including:
a resistor having a terminal coupled to the first terminal of the transistor and the input terminal of the comparator circuitry;
level shifter circuitry having an input terminal and an output terminal, the input terminal of the level shifter circuitry is coupled to the output terminal of the comparator circuitry; and
buffer circuitry having an input terminal and an output terminal, the input terminal of the buffer circuitry is coupled to the output terminal of the level shifter circuitry, the output terminal of the buffer circuitry is coupled to the input terminal of the inverter.

7. The apparatus of claim 1, wherein the second LC circuitry has a first terminal and a second terminal, and the apparatus further comprising:
receiver circuitry having a first input terminal, a second input terminal, and an output terminal, the first input terminal of the receiver circuitry is coupled to the first terminal of the second LC circuitry, the second input terminal of the receiver circuitry is coupled to second terminal of the second LC circuitry;
deglitch circuitry having an input terminal and an output terminal, the input terminal of the deglitch circuitry is coupled to the output terminal of the receiver circuitry; and
a transistor having a control terminal coupled to the output terminal of the deglitch circuitry.

8. An apparatus comprising:
charge injection circuitry having a first terminal, a second terminal, and a control terminal;
a transformer having a first input terminal, a second input terminal, a first output terminal, and a second output terminal, the first input terminal of the transformer is coupled to the first terminal of the charge injection circuitry, the second input terminal of the transformer is coupled to the second terminal of the charge injection circuitry;
current sense circuitry having an input terminal coupled to the control terminal of the charge injection circuitry; and
receiver circuitry having a first input terminal and a second input terminal, the first input terminal of the receiver circuitry is coupled to the first output terminal of the transformer, the second input terminal of the receiver circuitry is coupled to the second output terminal of the transformer.

9. The apparatus of claim 8, wherein the charge injection circuitry includes:
current source circuitry having a first terminal and a control terminal;
a first transistor having a first terminal, a second terminal, and a control terminal; and
a second transistor having a first terminal, a second terminal, and a control terminal, the first terminal of the second transistor is coupled to the first terminal of the current source circuitry and the first terminal of the first transistor, the second terminal of the second transistor is coupled to the first input terminal of the transformer and the control terminal of the first transistor, the control terminal of the second transistor is coupled to the second input terminal of the transformer and the second terminal of the first transistor.

10. The apparatus of claim 9, wherein the current source circuitry is a third transistor having a first terminal and a control terminal, the first terminal of the third transistor is coupled to the first terminal of the first transistor and the first terminal of the second transistor, the control terminal of the third transistor is coupled to the input terminal of the current sense circuitry.

11. The apparatus of claim 8, wherein the transformer including:
first inductor-capacitor (LC) circuitry having a first terminal and a second terminal, the first terminal of the first LC circuitry is coupled to the first terminal of the charge injection circuitry, the second terminal of the first LC circuitry is coupled to the second terminal of the charge injection circuitry; and
second LC circuitry having a first terminal and a second terminal, the first terminal of the second LC circuitry is coupled to the first input terminal of the receiver circuitry, the second terminal of the second LC circuitry is coupled to the second input terminal of the receiver circuitry, the second LC circuitry is magnetically coupled to the first LC circuitry.

12. The apparatus of claim 8, wherein the charge injection circuitry, the transformer, and the receiver circuitry are first gate driver circuitry, the first gate driver circuitry having an output terminal, and the apparatus further comprising:
second gate driver circuitry having an output terminal;
third gate driver circuitry having an output terminal; and
a motor having a first terminal, a second terminal, and a third terminal, the first terminal of the motor is coupled to the output terminal of the first gate driver circuitry, the second terminal of the motor is coupled to the output terminal of the second gate driver circuitry, the third terminal of the motor is coupled to the output terminal of the third gate driver circuitry.

13. The apparatus of claim 8, wherein the current sense circuitry including:
a transistor having a first terminal and a control terminal, the control terminal of the transistor is coupled to the control terminal of the charge injection circuitry;
comparator circuitry having an input terminal and an output terminal, the input terminal of the comparator circuitry is coupled to the first terminal of the transistor; and
an inverter having an input terminal coupled to the output terminal of the comparator circuitry.

14. The apparatus of claim 8, wherein the receiver circuitry further has an output terminal, and the apparatus further comprising:
deglitch circuitry having an input terminal and an output terminal, the input terminal of the deglitch circuitry is coupled to the output terminal of the receiver circuitry; and
a transistor having a control terminal coupled to the output terminal of the deglitch circuitry.

15. An apparatus comprising:
gate driver circuitry configured to:
receive a pulse width modulation (PWM) signal;
generate a current based on a logical state of the PWM signal; and
generate a sinusoidal signal in response to the current; and
current sense circuitry configured to:
sense the generation of the current by the gate driver circuitry; and
set a logical state of a safe signal in response to sensing the generation of the current.

16. The apparatus of claim 15, wherein the gate driver circuitry is further configured to inject the current into inductor-capacitor (LC) circuitry to generate the sinusoidal signal.

17. The apparatus of claim 15, wherein the current sense circuitry is further configured to:
set the logical state of the safe signal to a first logical state in response to the gate driver circuitry generating the current; and
set the logical state of the safe signal to a second logical state in response to the gate driver circuitry not generating the current.

18. The apparatus of claim 15, wherein the current sense circuitry is further configured to invert the safe signal.

19. The apparatus of claim 15, wherein the current sense circuitry is further configured to disable the gate driver circuitry in response to setting the safe signal to a logical state matching the logical state of the PWM signal.

20. The apparatus of claim 15, wherein the PWM signal is a first PWM signal, and the gate driver circuitry is further configured to:
transmit the sinusoidal signal across an isolation barrier;
generate a second PWM signal in response to the sinusoidal signal traversing the isolation barrier; and
deglitch pulses of the second PWM signal having a duration less than a minimum duration.
